(19) United States
(12) Patent Application Publication
(10) Pub. No.: US 2024/0071724 A1
(43) Pub. Date: Feb. 29, 2024

(54) METHOD AND DEVICE FOR MATCHING IMPEDANCE OF PULSE RADIO FREQUENCY PLASMA

(71) Applicant: Advanced Micro-Fabrication Equipment Inc. China, Shanghai (CN)

(72) Inventors: Rubin YE, Shanghai (CN); Leyi TU, Shanghai (CN); Lawrence Chung-Lai LEI, Shanghai (CN)

(21) Appl. No.: 18/388,121

(22) Filed: Nov. 8, 2023

Related U.S. Application Data
(62) Division of application No. 16/705,156, filed on Dec. 5, 2019, now abandoned.

(30) Foreign Application Priority Data
Dec. 7, 2018 (CN) 201811495750.5
Dec. 7, 2018 (CN) 201811495777.4

(51) Int. Cl. H01J 37/32; H03H 7/38; H03H 7/40; H03H 7/46; H03H 11/28; H03H 11/30; H05H 1/46

(52) U.S. Cl. CPC H01J 37/32183; H03H 7/38; H03H 7/40; H03H 7/46; H03H 11/28; H03H 11/30; H05H 1/46

(57) ABSTRACT

A method and a device for matching an impedance of pulse radio frequency plasma, and a plasma processing device are provided. In the method, a matched frequency is searched for sequentially in high radio frequency power phases of an i-th pulse period and multiple pulse periods following the i-th pulse period, and a specific modulation frequency determined in a process of searching for the matched frequency in a previous pulse is assigned as an initial frequency for the subsequent pulse. In this way, it is equivalent to increasing a width of a first radio frequency power phase of a pulse period. Therefore, by sequentially performing frequency modulation in the first radio frequency power phases of the multiple pulses, a matched frequency of pulse radio frequency plasma of a high pulse frequency can be found, thereby achieving impedance matching of plasma of a high pulse frequency.

The present application is a divisional of co-pending U.S. patent application Ser. No. 16/705,156 filed on Dec. 5, 2019, which claims priority to Chinese Patent Application No. 201811495750.5 filed on Dec. 7, 2018, and Chinese Patent Application No. 201811495777.4 filed on Dec. 7, 2018 with the China Patent Office, which are incorporated herein by reference in their entireties.

### FIELD

The present disclosure relates to the field of pulse radio frequency plasma, and in particular to a method and a device for matching an impedance of pulse radio frequency plasma.

### BACKGROUND

Radio frequency power of pulse radio frequency plasma includes high output power and low output power. Accordingly, an impedance of the plasma includes an impedance in a high power state and an impedance in a low power state. In the technology of frequency modulation for matching the impedance of plasma, in order to solve a problem of frequency mismatching due to a sudden jitter of the radio frequency, two different matched radio frequencies are required to respectively match the impedance in the high power state and the impedance in the low power state of the plasma. Therefore, the technology of automatic frequency modulation for impedance matching is required to find matched frequencies for a high power phase and a lower power phase of the radio frequency power.

In the conventional technology of automatic frequency modulation for impedance matching, the frequency modulation are required to be performed for several or dozens of times (approximately in a time period of 5 μs to 10 μs) so as to find the matched frequency. This frequency modulation rate can fully satisfy the impedance matching for the high power phase and the lower power phase of the pulse radio frequency plasma of a medium or low pulse frequency (for example, 100 Hz to 1000 Hz). For pulse radio frequency plasma of a high pulse frequency, for example, 5000 Hz, since the pulse width is narrow, the number of times of frequency modulation that can be performed in each pulse period is small. Therefore, it is difficult to find a matched frequency in a period of a single pulse of the pulse radio frequency plasma of a high pulse frequency by using the conventional technology of automatic frequency modulation for impedance matching, failing to achieve the impedance matching of the plasma of a high pulse frequency.

### SUMMARY

In view of above, a method and a device for matching an impedance of pulse radio frequency plasma are provided in the present disclosure, to find a matched frequency of pulse radio frequency plasma of a high pulse frequency, thereby achieving impedance matching of plasma of a high pulse frequency.

The following technical solutions are provided in the present disclosure.

A method for matching an impedance of pulse radio frequency plasma is provided according to a first aspect of the present disclosure. The method includes: receiving pulse radio frequency power to a plasma reaction chamber, where the pulse radio frequency power includes n pulse periods each including a first radio frequency power phase, the first radio frequency power phase is a high radio frequency power phase or a low radio frequency power phase, and n is a positive integer; selecting an i-th pulse period and multiple candidate pulse periods following the i-th pulse period, where i is a positive integer less than n; acquiring a first initial frequency for the first radio frequency power phase of the i-th pulse period; searching for a matched frequency sequentially in the first radio frequency power phases of each of the i-th pulse period and multiple candidate pulse periods following the i-th pulse period based on the first initial frequency, until an impedance parameter corresponding to a modulation frequency reaches an extreme value, where in the i-th pulse period and the multiple candidate pulse periods following the i-th pulse period, a specific modulation frequency determined in the first radio frequency power phase of a previous pulse period is taken as an initial frequency for the first radio frequency power phase of a subsequent pulse period; and determining the modulation frequency corresponding to the impedance parameter reaching the extreme value as the matched frequency matching the impedance of the pulse radio frequency plasma in the first radio frequency power phase of the pulse radio frequency power.

In an embodiment, the selecting an i-th pulse period and multiple candidate pulse periods following the i-th pulse period includes: selecting one of the n pulse periods as the i-th pulse period; and selecting multiple consecutive pulse periods immediately following the i-th pulse period as the multiple candidate pulse periods.

In an embodiment, the selecting an i-th pulse period and multiple candidate pulse periods following the i-th pulse period includes: selecting one of the n pulse periods as the i-th pulse period; and selecting multiple inconsecutive pulse periods at an interval of at least one pulse period from the i-th pulse period as the multiple candidate pulse periods.

In an embodiment, the selecting an i-th pulse period and multiple candidate pulse periods following the i-th pulse period includes: dividing the n pulse periods into multiple radio frequency modulation paths each including at least two inconsecutive pulse periods; and selecting, for each of the radio frequency modulation paths, an initial pulse period in the radio frequency modulation path as the i-th pulse period, and other pulse periods than the initial pulse period in the radio frequency modulation path as the multiple candidate pulse periods.

In an embodiment, the selecting an i-th pulse period and multiple candidate pulse periods following the i-th pulse period includes: dividing the n pulse periods into K consecutive radio frequency modulation sections each including at least one pulse period, where K is a positive integer greater than or equal to 2; selecting each pulse period in a k-th radio frequency modulation section as the i-th pulse period, where k is a positive integer less than K; and selecting pulse periods in multiple radio frequency modulation sections following the k-th radio frequency modulation section as the multiple candidate pulse periods. The specific modulation frequency determined in first radio frequency power phases of pulse periods of a previous radio frequency modulation section is taken as an initial frequency for the first radio frequency power phase of each pulse period of a subsequent radio frequency modulation section.

In an embodiment, each of the radio frequency modulation paths includes multiple inconsecutive pulse periods at equal intervals.

In an embodiment, numbers of pulse periods in the K consecutive radio frequency modulation sections are set as any integer values.

In an embodiment, the multiple radio frequency modulation sections following the k-th radio frequency modulation section are multiple consecutive radio frequency modulation sections immediately following the k-th radio frequency modulation section.

In an embodiment, the multiple radio frequency modulation sections following the k-th radio frequency modulation section are multiple inconsecutive radio frequency modulation sections at an interval of at least one radio frequency modulation section from the k-th radio frequency modulation section.

In an embodiment, the first initial frequency is a manually assigned frequency or a frequency obtained from previous automatic frequency modulation.

In an embodiment, the specific modulation frequency determined in the first radio frequency power phase of the previous pulse period is determined by: acquiring multiple modulation frequencies used in searching for the matched frequency in the first radio frequency power phase of the previous pulse period and multiple impedance parameters corresponding to the multiple modulation frequencies; comparing the multiple impedance parameters; and determining a modulation frequency corresponding to the smallest one of the multiple impedance parameters as the specific modulation frequency.

In an embodiment, the specific modulation frequency determined in the first radio frequency power phase of the previous pulse period is determined as: a frequency most matching the impedance of the plasma among modulation frequencies used in searching for the matched frequency in the first radio frequency power phase of the pulse period, or a modulation frequency randomly determined from modulation frequencies used in searching for the matched frequency in the first radio frequency power phase of the previous pulse period.

In an embodiment, the impedance parameter is reflection power, a reflection coefficient or impedance.

A plasma processing device is provided according to another aspect of the present disclosure. The plasma processing device includes a plasma reaction chamber and a radio frequency power generator. The plasma reaction chamber is configured to accommodate and process a substrate. The radio frequency power generator is configured to output pulse radio frequency power to the plasma reaction chamber. The pulse radio frequency power includes n pulse periods each including a first radio frequency power phase. The first radio frequency power phase is a high radio frequency power phase or a low radio frequency power phase, and n is a positive integer. The radio frequency power generator includes an automatic frequency modulation device. The automatic frequency modulation device is configured to perform any of the above methods for matching an impedance of pulse radio frequency plasma.

In an embodiment, the plasma processing device further includes a random command generator. The random command generator is configured to set a radio frequency modulation section length, and transmit a signal of the set radio frequency modulation section length to the radio frequency power generator, so that the radio frequency power generator divides the n pulse periods into multiple radio frequency modulation sections based on the signal of the set radio frequency modulation section length.

Compared with the conventional technology, the present disclosure has the following beneficial effects.

It can be seen based on the above technical solutions that, in the method for matching an impedance of pulse radio frequency plasma, first, a first initial frequency for the first radio frequency power phase of an i-th pulse period is acquired. Next, based on the first initial frequency, a matched frequency is searched for sequentially in first radio frequency power phases of the i-th pulse period and the multiple pulse periods following the i-th pulse period, until an impedance parameter corresponding to a modulation frequency reaches an extreme value. Finally, the modulation frequency corresponding to the impedance parameter reaching the extreme value is determined as the matched frequency matching the impedance of the plasma in the first radio frequency power phase of the pulse radio frequency power.

In the process of sequentially searching for the matched frequency in the first radio frequency power phases of the i-th pulse period and the multiple pulse periods following the i-th pulse period, a specific modulation frequency determined in a process of searching for the matched frequency in a previous pulse period is assigned as an initial frequency for the subsequent pulse period. In this way, it is equivalent to increasing a width of a first radio frequency power phase of a pulse period. Therefore, by sequentially performing frequency modulation in the first radio frequency power phases of the multiple pulses, a matched frequency of pulse radio frequency plasma of a high pulse frequency can be found, thereby achieving impedance matching of plasma of a high pulse frequency.

### BRIEF DESCRIPTION OF THE DRAWINGS

In order to more clearly illustrate technical solutions in embodiments of the present disclosure or in the conventional technology, the drawings to be used in the description of the embodiments or the conventional technology are briefly described below. Apparently, the drawings in the following description show only some embodiments of the present disclosure, and other drawings may be obtained by those skilled in the art from the drawings without any creative work.

FIG. 1 is a schematic diagram showing a relationship between reflection power and a frequency of a radio frequency (RF) source;

FIG. 2 is a flowchart of a method for matching an impedance of pulse radio frequency plasma according to an embodiment of the present disclosure;

FIG. 3 is a schematic diagram showing pulse radio frequency power according to an embodiment of the present disclosure;

FIG. 4 is a flowchart of a method for matching an impedance of pulse radio frequency plasma according to an embodiment of the present disclosure;

FIG. 5 is a schematic diagram showing principles of a method for matching an impedance of pulse radio frequency plasma according to an embodiment of the present disclosure;

FIG. 6 is a flowchart of a method for matching an impedance of pulse radio frequency plasma according to another embodiment of the present disclosure;

FIG. 7 is a schematic diagram showing principles of the method for matching an impedance of pulse radio frequency plasma according to another embodiment of the present disclosure;

FIG. 8 is a flowchart of a method for matching an impedance of pulse radio frequency plasma according to another embodiment of the present disclosure;

FIG. 9 is a schematic diagram showing principles of the method for matching an impedance of pulse radio frequency plasma according to another embodiment of the present disclosure;

FIG. 10 is a flowchart of a method for acquiring a first matched frequency according to an embodiment of the present disclosure;

FIG. 11 is a flowchart of a method for acquiring a second matched frequency according to an embodiment of the present disclosure;

FIG. 12a is a schematic diagram of dividing pulse radio frequency power into multiple radio frequency modulation sections according to an embodiment of the present disclosure;

FIG. 12b is a schematic diagram of dividing the pulse radio frequency power into multiple radio frequency modulation sections according to another embodiment of the present disclosure;

FIG. 13 is a flowchart of a method for matching an impedance of pulse radio frequency plasma according to another embodiment of the present disclosure;

FIG. 14 is a flowchart of a method for matching an impedance of pulse radio frequency plasma according to an embodiment of the present disclosure;

FIG. 15 is a schematic diagram showing principles of the method for matching an impedance of pulse radio frequency plasma according to an embodiment of the present disclosure;

FIG. 16 is a schematic structural diagram of a device for matching an impedance of pulse radio frequency plasma according to an embodiment of the present disclosure;

FIG. 17 is a schematic structural diagram of a device for matching an impedance of pulse radio frequency plasma according to another embodiment of the present disclosure;

FIG. 18 is a schematic structural diagram of a device for matching an impedance of pulse radio frequency plasma according to another embodiment of the present disclosure; and

FIG. 19 is a schematic structural diagram of a plasma processing device according to an embodiment of the present disclosure.

### DETAILED DESCRIPTION OF EMBODIMENTS

Before describing specific embodiments of the present disclosure, information of a load impedance of a radio frequency power transmission system is provided.

The load impedance of the radio frequency power transmission system depends on impedance of a transmission line, impedance of an impedance matching network, and impedance of a plasma chamber. It is verified from experiments that a relationship between any parameter related to a load impedance of a plasma reaction chamber and a frequency of a RF source is a nonlinear function, and the nonlinear function has an extreme value. Further, in a case that the load impedance matches an impedance of the RF source, any parameter related to the load impedance reaches its extreme value.

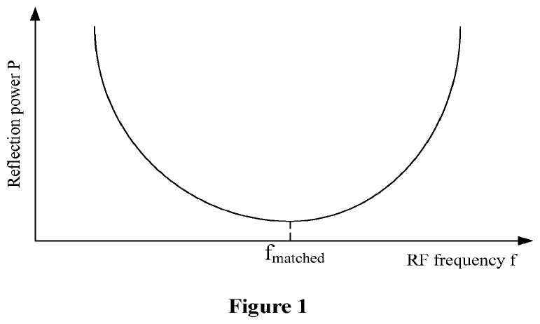

There are plenty of impedance parameters related to the load impedance of the plasma reaction chamber, such as reflection power, a reflection coefficient or impedance. For example, FIG. 1 is a schematic diagram showing a relationship between reflection power and a frequency of an RF source. As shown in FIG. 1, a relationship between the reflection power and the frequency of the RF source is a nonlinear function having a minimum value. In a case that the load impedance matches the impedance of the RF source, the reflection power reaches the minimum value. Further, it may be considered that a matched frequency value and a reflection power value corresponding to the matched frequency are located at an inflection point of the relationship curve.

The method for matching an impedance of pulse radio frequency plasma in the present disclosure is proposed based on the above principles. Specific embodiments of the method for matching an impedance of pulse radio frequency plasma in the present disclosure are described in detail below with reference to the drawings.

Radio frequency power of the pulse radio frequency plasma has a high radio frequency power phase and a low radio frequency power phase. In a case that the radio frequency power in the low radio frequency power phase is zero, only an impedance of the plasma in the high radio frequency power phase is required to be matched. In a case that the radio frequency power in the low radio frequency power phase is not zero, both the impedance of the plasma in the high radio frequency power phase and an impedance of the plasma in the low radio frequency power phase are required to be matched. In addition, as described in the Background, in order to solve the problem of frequency mismatching due to a sudden jitter of radio frequency, frequency modulation is required to be performed separately in the high radio frequency power phase and in the low radio frequency power phase.

However, in the conventional technology of automatic frequency modulation for impedance matching, a time period required for frequency modulation is longer than a pulse period of a radio frequency power of a high pulse frequency, and the matched frequency cannot be found in a single pulse phase, thus the impedance matching of the plasma of a high pulse frequency cannot be achieved.

Table 1 lists the number of times of frequency modulation that can be performed in a single low power pulse period at various pulse frequencies. It should be noted that, in Table 1, a time period for each frequency modulation is assumed to be 10 μs, as an example.

TABLE 1

| Duty cycle of | Pulse frequency | | | | | | |
|---|---|---|---|---|---|---|---|
| high power | 100 | 500 | 1000 | 2000 | 3000 | 4000 | 5000 |
| pulse | Hz | Hz | Hz | Hz | Hz | Hz | Hz |
| 25% | 750 | 150 | 75 | 37 | 25 | 19 | 15 |
| 50% | 500 | 100 | 50 | 25 | 17 | 12 | 10 |
| 75% | 250 | 50 | 25 | 12 | 8 | 6 | 5 |

It can be seen from Table 1 that, for pulse plasma of a high pulse frequency, the number of times of frequency modulation that can be performed in a single pulse period is less than 10. Therefore, it is difficult to find the matched frequency in the single pulse period by the technology of automatic frequency modulation.

The above problem is caused by the fact that a rate at which a power generator generates a frequency cannot match with a rate at which the modulation frequency is modulated, which is a problem of frequency mismatching of the power generator. In order to solve the above technical problem, it is important for the power generator to have a function of frequency reading and frequency assigning.

Based on this, a method for matching an impedance of pulse radio frequency plasma is provided in the present disclosure. In the method, first, a first initial frequency for the first radio frequency power phase of an i-th pulse period is acquired. Next, based on the first initial frequency, a matched frequency is searched for sequentially in the first radio frequency power phase of each of the i-th pulse period and the multiple pulse periods following the i-th pulse period, until an impedance parameter corresponding to a modulation frequency reaches an extreme value. Finally, the modulation frequency corresponding to the impedance parameter reaching the extreme value is determined as the matched frequency matching the impedance of the plasma in the first radio frequency power phase of the pulse radio frequency power.

In the process of sequentially searching for the matched frequency in the first radio frequency power phases of the i-th pulse period and the multiple pulse periods following the i-th pulse period, a specific modulation frequency determined in a process of searching for the matched frequency in a previous pulse is assigned as an initial frequency for the subsequent pulse. In this way, it is equivalent to increasing a width of a first radio frequency power phase of a pulse period. Therefore, by performing frequency modulation sequentially in the first radio frequency power phases of the multiple pulses, a matched frequency of pulse radio frequency plasma of a high pulse frequency can be found, thereby achieving impedance matching for plasma of a high pulse frequency.

In order to make the technical problems, the technical solutions and the technical effects of the present disclosure more clear, the specific embodiments of the method for matching an impedance of pulse radio frequency plasma in the present disclosure are described in detail below with reference to the drawings.

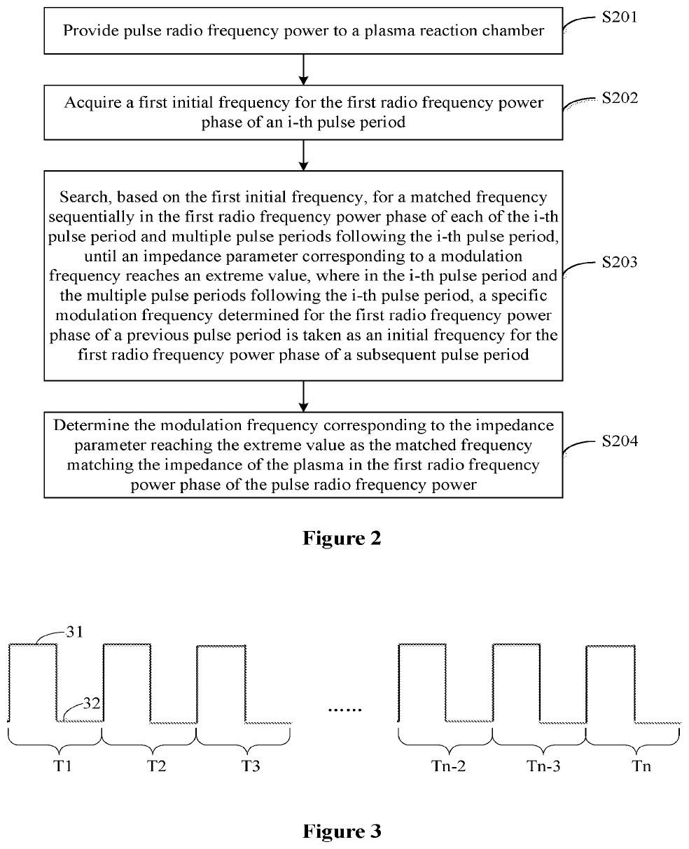

Reference is made to FIG. 2, which is a flowchart of a method for matching an impedance of pulse radio frequency plasma according to an embodiment of the present disclosure.

A method for matching an impedance of pulse radio frequency plasma provided according to the embodiment of the present disclosure includes the following steps S201 to S204.

In step S201, pulse radio frequency power is provided to a plasma reaction chamber.

It should be noted that, the pulse radio frequency power provided to the plasma reaction chamber includes n pulse periods, where n is positive integer. Each of the n pulse periods includes a first radio frequency power phase. The first radio frequency power phase is a high radio frequency power phase or a low radio frequency power phase.

For example, FIG. 3 is a schematic diagram showing an example of pulse radio frequency power. As shown in FIG. 3, the pulse radio frequency power includes n pulse periods. Each of the n pulse periods includes a high radio frequency power phase 31 and a low radio frequency power phase 32.

Frequency modulation is required to be performed separately in the high radio frequency power phase and the low radio frequency power phase. Therefore, the first radio frequency power phase may be the high radio frequency power phase 31 or the low radio frequency power phase 32 in the embodiments of the present disclosure.

In step S202, a first initial frequency for the first radio frequency power phase of an i-th pulse period is acquired, where i is a positive integer less than n.

The i-th pulse period may be any one of the first pulse period to the (n−1)-th pulse period in the pulse radio frequency power.

As an example, an embodiment of the present disclosure is described by taking the first pulse period as the i-th pulse period.

The first initial frequency may be acquired in various manners. In an example, the first initial frequency may be a manually assigned frequency. In another example, the first initial frequency may be a frequency obtained from previous automatic frequency modulation.

In step S203, based on the first initial frequency, a matched frequency is sequentially searched for in the first radio frequency power phase of each of the i-th pulse period and multiple pulse periods following the i-th pulse period, until an impedance parameter corresponding to a modulation frequency reaches an extreme value. In the i-th pulse period and the multiple pulse periods following the i-th pulse period, a specific modulation frequency determined in the first radio frequency power phase of a previous pulse period is taken as an initial frequency for the first radio frequency power phase of a subsequent pulse period.

In an example, step S203 may include the following sub-steps S203a to S203f.

In sub-step S203a, a matched frequency is searched for in the first radio frequency power phase of the i-th pulse period based on the first initial frequency. An acquired specific modulation frequency is read and stored as a first modulation frequency.

It should be noted that, in a process of searching for the matched frequency, a radio frequency may be modulated for multiple times based on a time period for frequency modulation and a pulse width in the first radio frequency power phase, to obtain multiple modulation frequencies.

In sub-step S203b, it is determined whether impedance parameters corresponding to the multiple modulation frequencies in the process of searching for the matched frequency reach an extreme value. If it is determined that an impedance parameter corresponding to one of the multiple modulation frequencies in the process of searching for the matched frequency reaches the extreme value, step S204 is performed. If it is determined that none of impedance parameters corresponding to the multiple modulation frequencies in the process of searching for the matched frequency reaches the extreme value, sub-step S203c is performed.

In sub-step S203c, the first modulation frequency is assigned to the first radio frequency power phase of an (i+k)-th pulse period, as a second initial frequency for the first radio frequency power phase of the (i+k)-th pulse period, where k is a positive integer and, i+k≤n.

In sub-step S203d, a matched frequency is searched for in the first radio frequency power phase of the (i+k)-th pulse period based on the second initial frequency. An acquired specific modulation frequency is read and stored as a second modulation frequency.

A process of searching for the matched frequency is the same as that in sub-step S203a, and is not described in detail herein for brevity.

In sub-step S203e, it is determined whether impedance parameters corresponding to modulation frequencies in the process of searching for the matched frequency reach an extreme value. If it is determined that an impedance parameter corresponding to one of the multiple modulation frequencies in the process of searching for the matched frequency reaches the extreme value, step S204 is performed. If it is determined that none of impedance parameters corresponding to the multiple modulation frequencies in the process of searching for the matched frequency reaches the extreme value, step S203f is performed.

It should be noted that the process of searching for the matched frequency described in this step refers to all processes of searching for the matched frequency from the initial searching performed in the i-th pulse period to the searching performed in the current pulse period.

In sub-step S203f, a value of i is updated by i=i+k. The second modulation frequency is taken as a second initial frequency for the first radio frequency power phase of a (i+k)-th pulse period, and the method returns to sub-step S203d.

In an example, the multiple pulse periods following the i-th pulse period may be multiple consecutive pulse periods immediately following the i-th pulse period. In another example, the multiple pulse periods following the i-th pulse period may be multiple pulse periods at an interval of at least one pulse period from the i-th pulse period and at an interval of at least one pulse period from each other.

In a case that the multiple pulse periods following the i-th pulse period are multiple consecutive pulse periods immediately following the i-th pulse period, the multiple pulse periods may be an (i+1)-th pulse period, an (i+2)-th pulse period, . . . , and an (i+m)-th pulse period, where m is a positive integer and i+m≤n.

For ease of illustration and description, an example that the first pulse period is taken as the i-th pulse period is described. The multiple pulse periods following the first pulse period may be the second pulse period, the third pulse period, . . . , and the t-th pulse period, where t is a positive integer and t≤n.

In a case that the multiple pulse periods following the i-th pulse period are multiple pulse periods at an interval of at least one pulse period from the i-th pulse period and at an interval of at least one pulse period from each other, the multiple pulse periods may be an (i+k)-th pulse period, an (i+2k)-th pulse period, . . . , and an (i+Nk)-th pulse period, where k is a positive integer and i+Nk≤n.

For ease of illustration and description, an example that the first pulse period is taken as the i-th pulse period, and the pulse periods are at an interval of one pulse period is described in the following description. The multiple pulse periods following the first pulse period may be the third pulse period, the fifth pulse period, . . . , and the (2K−1)-th pulse period, where K is a positive integer and 2K−1≤n.

It should be noted that, in the embodiments of the present disclosure, the impedance parameter may be reflection power, a reflection coefficient or impedance. For each of the different impedance parameters, the nonlinear function between the impedance parameter and the frequency of the RF source may have a maximum value or a minimum value. Accordingly, an extreme value of the impedance parameter may be a minimum value or a maximum value. For example, in a case that the impedance parameter is the reflection power, the extreme value of the impedance parameter is a minimum value.

In addition, the specific modulation frequency may be differently determined in the process of searching for the matched frequency. In an example, the specific modulation frequency may be a frequency most matching the impedance of the plasma that is found in the first radio frequency power phase of a pulse period in which the specific modulation frequency is determined. In another example, the specific modulation frequency may be a modulation frequency randomly determined from modulation frequencies used in the modulation process in a first radio frequency power phase of a pulse period in which the specific modulation frequency is determined.

In another example, the specific modulation frequency may be a modulation frequency corresponding to the smallest one of the multiple impedance parameters corresponding to modulation frequencies obtained in the process of searching for the matched frequency in the first radio frequency power phase of a pulse period in which the specific modulation frequency is determined. In this case, step S203 may include sub-steps of: acquiring, for each of the multiple pulse periods, modulation frequencies obtained in the process of searching for the matched frequency in the first radio frequency power phase of the pulse period and impedance parameters corresponding to the modulation frequencies; comparing the impedance parameters; and determining a modulation frequency corresponding to the smallest one of the multiple impedance parameters as the specific modulation frequency. In this case, step S203 may include the following sub-steps S2031 to S2038.

In sub-step S2031, a matched frequency is searched for in the first radio frequency power phase of the i-th pulse period based on the first initial frequency. Modulation frequencies obtained in the process of searching for the matched frequency in the first radio frequency power phase of the i-th pulse period and impedance parameters corresponding to the modulation frequencies are read and stored.

It should be noted that, in a process of searching for the matched frequency, a radio frequency may be modulated for multiple times based on a time period for frequency modulation and a pulse width in the first radio frequency power phase, to obtain multiple modulation frequencies.

In sub-step S2032, the impedance parameters corresponding to the modulation frequencies obtained in the process of searching for the matched frequency in the first radio frequency power phase of the i-th pulse period are compared to each other, and a modulation frequency corresponding to the smallest one of the multiple impedance parameters is acquired as a first modulation frequency.

In sub-step S2033, it is determined whether the impedance parameters corresponding to the modulation frequencies in the process of searching for the matched frequency reach an extreme value. If it is determined that an impedance parameter corresponding to one of the modulation frequencies in the process of searching for the matched frequency reaches the extreme value, step S204 is performed. If it is determined that none of the impedance parameters corresponding to the modulation frequencies in the process of searching for the matched frequency reaches the extreme value, sub-step S2034 is performed.

In sub-step S2034, the first modulation frequency is assigned to the first radio frequency power phase of an (i+k)-th pulse period, as a second initial frequency for the first radio frequency power phase of the (i+k)-th pulse period, where k is a positive integer and i+k≤n.

In sub-step S2035, a matched frequency is searched for in the first radio frequency power phase of the (i+k)-th pulse period based on the second initial frequency. Modulation frequencies obtained in a process of searching for the matched frequency in the first radio frequency power phase of the (i+k)-th pulse period and impedance parameters corresponding to the modulation frequencies are read and stored.

The process of searching for the matched frequency is the same as that in sub-step S2031, and is not described in detail herein for brevity.

In sub-step S2036, the impedance parameters corresponding to the modulation frequencies obtained in the process of searching for the matched frequency in the first radio frequency power phase of the (i+k)-th pulse period are compared, and a modulation frequency corresponding to the smallest one of the multiple impedance parameters is acquired a second modulation frequency.

In sub-step S2037, it is determined whether the impedance parameters corresponding to the modulation frequencies in the process of searching for the matched frequency reach an extreme value. If it is determined that an impedance parameter corresponding to one of the modulation frequencies in the process of searching for the matched frequency reaches the extreme value, step S204 is performed. If it is determined that none of the impedance parameters corresponding to the modulation frequencies in the process of searching for the matched frequency reaches the extreme value, step S2038 is performed.

It should be noted that the process of searching for the matched frequency described in this step refers to all processes of searching for the matched frequency from the initial searching performed in the i-th pulse period to the searching performed in the current pulse period.

In sub-step S2038, a value of i is updated by i=i+k. The second modulation frequency is taken as a second initial frequency for the first radio frequency power phase of a (i+k)-th pulse period, and the method returns to sub-step S2035.

In step 204, a modulation frequency corresponding to an impedance parameter reaching the extreme value is determined as a matched frequency matching the impedance of the plasma in the first radio frequency power phase of the pulse radio frequency power.

An embodiment of the method for matching an impedance of pulse radio frequency plasma is described above. In this embodiment, first, a first initial frequency for the first radio frequency power phase of an i-th pulse period is acquired. Next, based on the first initial frequency, a matched frequency is sequentially searched for in the first radio frequency power phases of the i-th pulse period and the multiple pulse periods following the i-th pulse period, until an impedance parameter corresponding to a determined specific modulation frequency reaches an extreme value. Finally, the modulation frequency corresponding to the impedance parameter reaching the extreme value is determined as the matched frequency matching the impedance of the plasma in the first radio frequency power phase of the pulse radio frequency power.

In the process of sequentially searching for the matched frequency in the first radio frequency power phases of the i-th pulse period and the multiple pulse periods following the i-th pulse period, a specific modulation frequency determined in a process of searching for the matched frequency in a previous pulse is assigned as an initial frequency for the subsequent pulse. In this way, it is equivalent to increasing a width of a first radio frequency power phase of a pulse period. Therefore, by performing frequency modulation sequentially in the first radio frequency power phases of the multiple pulses, a matched frequency of pulse radio frequency plasma of a high pulse frequency can be found, so that the impedance matching of the plasma is not limited in a single pulse, thereby achieving impedance matching for plasma of a high pulse frequency.

Furthermore, in this embodiment, the first radio frequency power phase may be a high radio frequency power phase or a low radio frequency power phase. Therefore, in this embodiment, different initial frequencies may be respectively set for the high radio frequency power phase and the low radio frequency power phase, so that matched modulation frequencies are searched for separately in the high radio frequency power phase and the low radio frequency power phase, thereby avoiding a sudden jitter of the frequency between the high radio frequency power phase and the low radio frequency power phase.

In order to more clearly understand the specific embodiments of the present disclosure, a process of searching for the matched frequency matching the impedance of the plasma in the high radio frequency power phase is described as an example below. The following embodiments are described with an example of taking the reflection power as the impedance parameter.

Three specific embodiments of the method for matching an impedance of pulse radio frequency plasma are described below one by one.

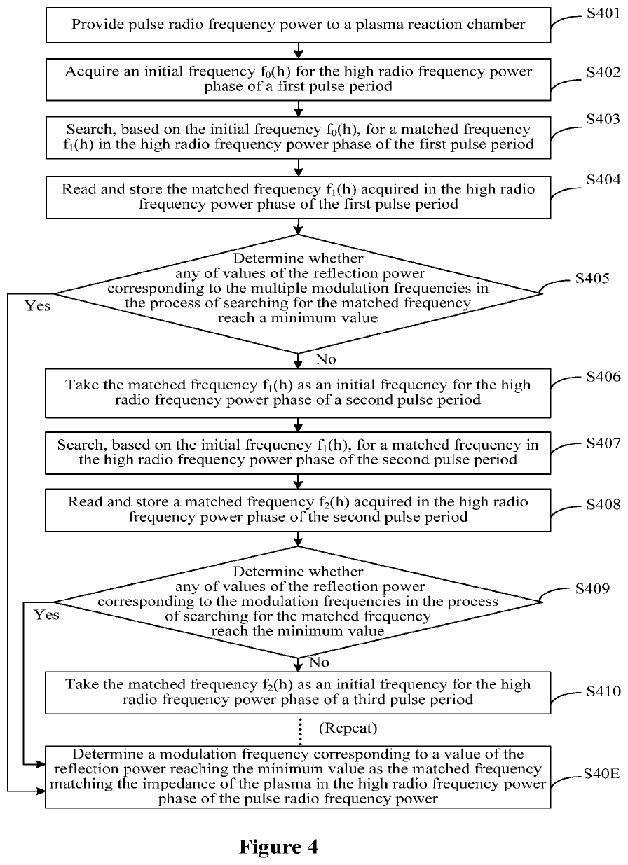

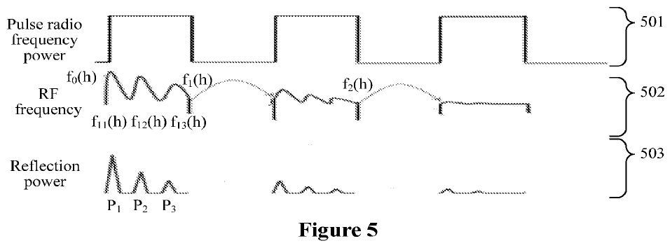

An embodiment of the method for matching an impedance of pulse radio frequency plasma is described in detail below with reference to FIGS. 4 and 5. FIG. 4 is a flowchart of a method for matching an impedance of pulse radio frequency plasma according to an embodiment of the present disclosure. FIG. 5 is a schematic diagram showing principles of the method for matching an impedance of pulse radio frequency plasma according to the embodiment of the present disclosure.

The method for matching an impedance of pulse radio frequency plasma according to the embodiment of the present disclosure may include the following steps S401 to S40E.

In step S401, pulse radio frequency power is provided to a plasma reaction chamber.

For example, the pulse radio frequency power may be pulse radio frequency power 501 shown in FIG. 5.

In step S402, an initial frequency f₀(h) for the high radio frequency power phase of a first pulse period is acquired.

For example, the initial frequency f₀(h) may be a frequency f₀(h) of an RF frequency 502 shown in FIG. 5.

In step S403, based on the initial frequency f₀(h), a matched frequency f₁(h) is searched for in the high radio frequency power phase of the first pulse period.

The matched frequency f₁(h) may be a frequency most matching the impedance of the plasma that is found in the high radio frequency power phase of the first pulse period.

In an example, step S403 may include the following sub-steps S403a to S403b.

In sub-step S403a, a matched frequency is searched for in the high radio frequency power phase of the first pulse period, where a frequency may be modulated for multiple times in the process of searching for the matched frequency.

In an example, the RF frequency is modulated for three times in the first pulse period shown in FIG. 5, to obtain modulation frequencies f₁₁(h), f₁₂(h) and f₁₃(h).

In sub-step S403b, in the high radio frequency power phase of the first pulse period, a modulation frequency corresponding to reflection power reaching a minimum value is selected as the matched frequency f₁(h).

A value of the reflection power varies with the modulation frequency. Different modulation frequencies correspond to different values of the reflection power.

For example, a value of the reflection power 502 shown in FIG. 5 varies with the RF frequency. The modulation frequency f₁₁(h) corresponds to reflection power P₁. The modulation frequency f₁₂(h) corresponds the reflection power P₂. The modulation frequency f₁₃(h) corresponds to reflection power P₃.

In an example, in sub-step S403b, if the reflection power P₂ corresponding to the modulation frequency f₁₂(h) shown in FIG. 5 reaches the minimum value, the modulation frequency f₁₂(h) is determined as the matched frequency f₁(h) in the high radio frequency power phase of the first pulse period.

It should be noted, in each of the pulse periods, a matched frequency is acquired in the above manner in the embodiments of the present disclosure.

In step S404, the matched frequency f₁(h) acquired in the high radio frequency power phase of the first pulse period is read and stored.

In step S405, it is determined whether any of values of the reflection power corresponding to the multiple modulation frequencies in the process of searching for the matched frequency reach the minimum value. If it is determined that one of the values of the reflection power corresponding to the modulation frequencies in the process of searching for the matched frequency reaches the minimum value, step S40E is performed. If it is determined that none of the values of the reflection power corresponding to the modulation frequencies in the process of searching for the matched frequency reaches the minimum value, step S406 is performed.

In step 406, the matched frequency f₁(h) is taken as an initial frequency for the high radio frequency power phase of a second pulse period.

In step S407, based on the initial frequency f₁(h), a matched frequency is searched for in the high radio frequency power phase of the second pulse period.

In step S408, a matched frequency f₂(h) acquired in the high radio frequency power phase of the second pulse period is read and stored.

In step S409, it is determined whether any of values of the reflection power corresponding to the modulation frequencies in the process of searching for the matched frequency reach the minimum value. If it is determined that one of the values of the reflection power corresponding to the modulation frequencies in the process of searching for the matched frequency reaches the minimum value, step S40E is performed. If it is determined that none of the values of the reflection power corresponding to the modulation frequencies in the process of searching for the matched frequency reaches the minimum value, step S410 is performed.

It should be noted that, the process of searching for the matched frequency described in this step includes the process of searching for the matched frequency in the first pulse period and the process of searching for the matched frequency in the second pulse period.

In step S410, the matched frequency f₂(h) is taken as an initial frequency for the high radio frequency power phase of a third pulse period.

Similarly, if the reflection power corresponding to a matched frequency read in the high radio frequency power phase of a previous pulse period does not reach the minimum value, the step of taking the matched frequency read in the high radio frequency power phase of the previous pulse period as an initial frequency for the high radio frequency power phase of a subsequent pulse period adjacent to the previous pulse period and searching for a matched frequency in the high radio frequency power phase of the subsequent pulse period adjacent to the previous pulse period is repeated, until a value of the reflection power corresponding to a read matched frequency reaches the minimum value. Then step S40E is performed.

In step S40E, a modulation frequency corresponding to a value of the reflection power reaching the minimum value is determined as the matched frequency matching the impedance of the plasma in the high radio frequency power phase of the pulse radio frequency power.

In the method for matching an impedance of pulse radio frequency plasma according to the embodiment of the present disclosure, a matched frequency is sequentially searched for in high radio frequency power phases of the i-th pulse period and multiple pulse periods immediately following the i-th pulse period, and a matched frequency found in a process of searching for the matched frequency in a previous pulse is assigned as an initial frequency for the subsequent pulse. In this way, it is equivalent to increasing a width of a high radio frequency power phase of a pulse period. Therefore, by performing frequency modulation sequentially in the high radio frequency power phases of the multiple pulses, a matched frequency of pulse radio frequency plasma of a high pulse frequency can be found, so that the impedance matching of the plasma is not limited in a single pulse, thereby achieving impedance matching for plasma of a high pulse frequency.

Furthermore, in this embodiment, a matched frequency acquired in the high radio frequency power phase of a previous pulse is taken as an initial frequency of a subsequent pulse. In this way, the number of times frequency modulation to be performed can be reduced, and efficiency of the frequency modulation can be improved.

In the above embodiment, the specific modulation frequency in a process of searching for the matched frequency in the high radio frequency power phase of each of the pulse periods is a frequency most matching the impedance of the plasma that is found in the high radio frequency power phase of the pulse period in which the specific modulation frequency is determined. The pulse periods used in the process of frequency modulation are consecutive pulse periods.

In an extension of the embodiment of the present disclosure, the specific modulation frequency determined in a process of searching for the matched frequency in the high radio frequency power phase of each of the pulse periods may be a modulation frequency randomly read in the process of searching for the matched frequency in a high radio frequency power phase of a pulse period in which the specific modulation frequency is determined. The extension of the embodiment is described and illustrated in detail below.

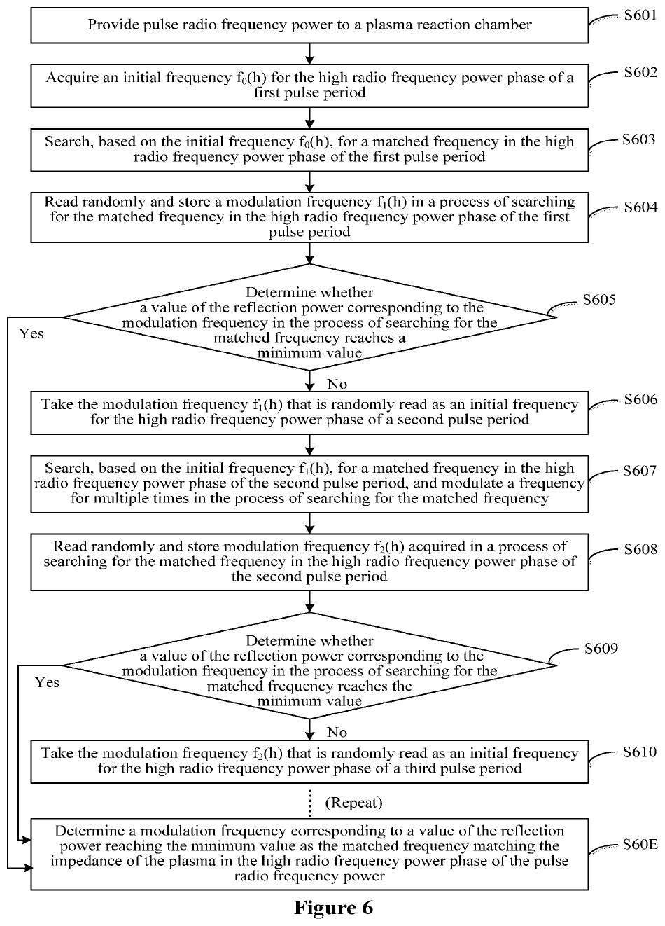

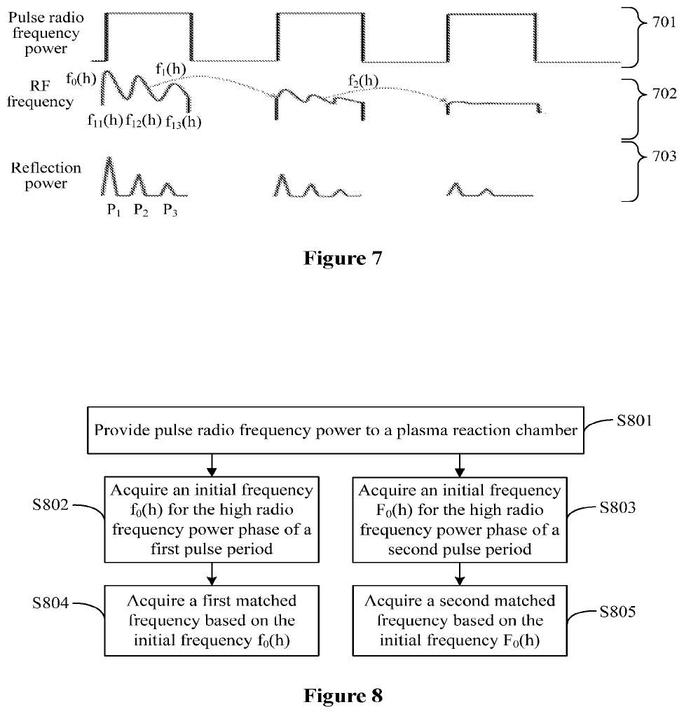

Another embodiment of the method for matching an impedance of pulse radio frequency plasma is described in detail below with reference to FIGS. 6 and 7. FIG. 6 is a flowchart of a method for matching an impedance of pulse radio frequency plasma according to the embodiment of the present disclosure. FIG. 7 is a schematic diagram showing principles of the method for matching an impedance of pulse radio frequency plasma according to the embodiment of the present disclosure.

The method for matching an impedance of pulse radio frequency plasma according to the embodiment of the present disclosure may include the following steps S601 to S60E.

In step S601, pulse radio frequency power is provided to a plasma reaction chamber.

For example, the pulse radio frequency power may be pulse radio frequency power 701 shown in FIG. 7.

In step S602, an initial frequency f₀(h) for the high radio frequency power phase of a first pulse period is acquired.

For example, the initial frequency f₀(h) may be a frequency f₀(h) of an RF frequency 702 shown in FIG. 7.

In step S603, based on the initial frequency f₀(h), a matched frequency is searched for in the high radio frequency power phase of the first pulse period.

In step S604, a modulation frequency f₁(h) in a process of searching for the matched frequency in the high radio frequency power phase of the first pulse period is read randomly and stored.

In an example, the RF frequency is modulated for three times in the first pulse period shown in FIG. 7, to obtain modulation frequencies f₁₁(h), f₁₂(h) and f₁₃(h). Therefore, in step S604, the modulation frequency that is randomly read may be any one of the modulation frequencies f₁₁(h), f₁₂(h) and f₁₃(h).

It should be noted that, in each of the pulse periods, a modulation frequency is acquired in the above manner in the embodiment of the present disclosure.

In step S605, it is determined whether a value of the reflection power corresponding to the modulation frequency f₁(h) in the process of searching for the matched frequency reaches a minimum value. If it is determined that the value of the reflection power corresponding to the modulation frequency f₁(h) in the process of searching for the matched frequency reaches the minimum value, step S60E is performed. If it is determined that the value of the reflection power corresponding to the modulation frequency f₁(h) in the process of searching for the matched frequency does not reach the minimum value, step S606 is performed.

In step S606, the modulation frequency f₁(h) that is randomly read is taken as an initial frequency for the high radio frequency power phase of a second pulse period.

In step S607, based on the initial frequency f₁(h), a matched frequency is searched for in the high radio frequency power phase of the second pulse period. The frequency is modulated for multiple times in the process of searching for the matched frequency.

In step S608, a modulation frequency f₂(h) acquired in a process of searching for the matched frequency in the high radio frequency power phase of the second pulse period is read randomly and stored.

In step S609, it is determined whether a value of the reflection power corresponding to the modulation frequency in the process of searching for the matched frequency reaches a minimum value. If it is determined that the value of the reflection power corresponding to the modulation frequency in the process of searching for the matched frequency reaches the minimum value, step S60E is performed. If it is determined that the value of the reflection power corresponding to the modulation frequency f₁(h) in the process of searching for the matched frequency does not reach the minimum value, step S610 is performed.

In step S610, the modulation frequency f₂(h) that is randomly read is taken as an initial frequency for the high radio frequency power phase of a third pulse period.

Similarly, if the reflection power corresponding to a modulation frequency in a process of searching for the matched frequency in the high radio frequency power phase of a previous pulse period does not reach the minimum value, the step of taking the modulation frequency that is randomly read in the high radio frequency power phase of the previous pulse period as an initial frequency for the high radio frequency power phase of a subsequent pulse period adjacent to the previous pulse period and searching for a matched frequency in the high radio frequency power phase of the subsequent pulse period adjacent to the previous pulse period is repeated, until the reflection power corresponding to the modulation frequency in a process of searching for the matched frequency reaches the minimum value. Then step S60E is performed.

In step S60E, a modulation frequency corresponding to a value of the reflection power reaching the minimum value is determined as the matched frequency matching the impedance of the plasma in the first radio frequency power phase of the pulse radio frequency power.

The alternative embodiment of the method for matching an impedance of pulse radio frequency plasma is provided. In this embodiment, the specific modulation frequency determined in a process of searching for the matched frequency in a high radio frequency power phase of each of the pulse periods is a modulation frequency randomly read in the process of searching for the matched frequency in a high radio frequency power phase of a pulse period in which the specific modulation frequency is determined. In the method, in a process of sequentially searching for the matched frequency in high radio frequency power phases of the i-th pulse period and multiple consecutive pulse periods following the i-th pulse period, a modulation frequency that is read randomly in a process of searching for the matched frequency in a previous pulse is assigned as an initial frequency for the subsequent pulse. In this way, it is equivalent to increasing a width of a high radio frequency power phase of a pulse period. Therefore, by performing frequency modulation sequentially in the high radio frequency power phases of the multiple pulses, a matched frequency of pulse radio frequency plasma of a high pulse frequency can be found, thereby achieving impedance matching for plasma of a high pulse frequency.

The above two embodiments are described with an example that the multiple pulse periods used in the process of frequency modulation are multiple consecutive pulse periods. In practice, the multiple pulse periods used in the process of frequency modulation may be multiple inconsecutive pulse periods, and the multiple pulse periods are at an interval of at least one pulse period from each other.

In an example, in a case that the multiple pulse periods are inconsecutive, the pulse radio frequency power including n pulse periods may be divided into multiple radio frequency modulation paths in advance. Impedance matching is performed for the pulse radio frequency plasma in each of the radio frequency modulation path, to obtain a matched frequency matching the impedance of the plasma in each of the radio frequency modulation path.

For ease of illustration and description, a case that the pulse radio frequency power including n pulse periods is divided into two radio frequency modulation paths is taken as an example in the following description.

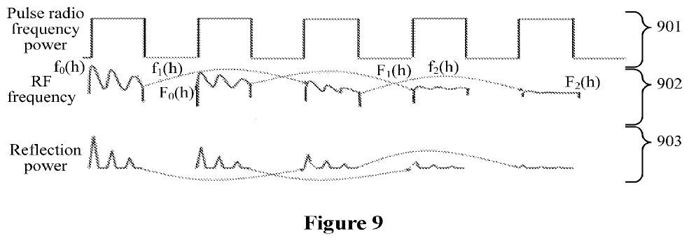

Another embodiment of the method for matching an impedance of pulse radio frequency plasma is described in detail below with reference to FIGS. 8 and 9. FIG. 8 is a flowchart of a method for matching an impedance of pulse radio frequency plasma according to the embodiment of the present disclosure. FIG. 9 is a schematic diagram showing principles of the method for matching an impedance of pulse radio frequency plasma according to the embodiment of the present disclosure.

The method for matching an impedance of pulse radio frequency plasma according to the embodiment of the present disclosure may include the following steps S801 to S805.

In step S801, pulse radio frequency power is provided to a plasma reaction chamber.

For example, the pulse radio frequency power may be pulse radio frequency power 901 shown in FIG. 9.

In step S802, an initial frequency f₀(h) for a high radio frequency power phase of a first pulse period is acquired.

The initial frequency f₀(h) may be a manually assigned frequency or a frequency obtained from previous automatic frequency modulation.

For example, the initial frequency f₀(h) may be a frequency f₀(h) of an RF frequency 902 shown in FIG. 9.

In step S803, an initial frequency F₀(h) for the high radio frequency power phase of a second pulse period is acquired.

The initial frequency F₀(h) may be a manually assigned frequency or a frequency obtained from previous automatic frequency modulation.

In an example, the initial frequency F₀(h) may be a frequency F₀(h) of an RF frequency 902 shown in FIG. 9.

It should be noted that, in the embodiments of the present disclosure, the initial frequency f₀(h) may be equal to or not equal to the initial frequency F₀(h).

In step S804, a first matched frequency is acquired based on the initial frequency f₀(h). A detailed implementation of this step is described in the following.

In step S805, a second matched frequency is acquired based on the initial frequency F₀(h). A detailed implementation of this step is described in the following.

It should be noted that, in the embodiments of the present disclosure, the order of step S802 and step S803 is not limited. Step S802 may be performed before step S803. Alternatively, step S803 may be performed before step S802. Further, the order of step S804 and step S805 is not limited. Step S804 may be performed before step S805. Alternatively, step S805 may be performed before step S804.

Hereinafter, detailed implementations of steps S804 and S805 are respectively described.

The detailed implementation of step S804 is described as follows.

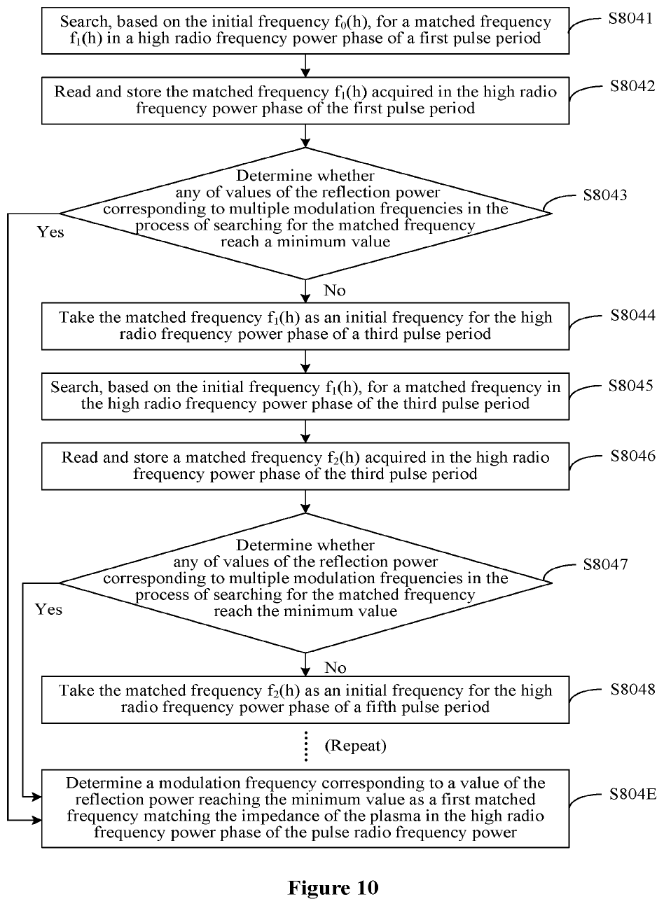

Reference is made to FIG. 10, which is a flowchart of a method for acquiring a first matched frequency according to the embodiment of the present disclosure.

In an example, step S804 may include the following sub-steps S8041 to S804E.

In sub-step S8041, based on the initial frequency f₀(h), a matched frequency f₁(h) is searched for in the high radio frequency power phase of the first pulse period.

It should be noted that, in the embodiments of the present disclosure, the matched frequency is searched for in a same manner in each pulse period.

In sub-step S8042, the matched frequency f₁(h) acquired in the high radio frequency power phase of the first pulse period is read and stored.

In sub-step S8043, it is determined whether any of values of the reflection power corresponding to multiple modulation frequencies in the process of searching for the matched frequency reach the minimum value. If it is determined that one of the values of the reflection power corresponding to the multiple modulation frequencies in the process of searching for the matched frequency reaches the minimum value, sub-step S804E is performed. If it is determined that none value of the reflection power corresponding to the multiple modulation frequencies in the process of searching for the matched frequency reaches the minimum value, sub-step S8044 is performed.

The reflection power may be reflection power 903 shown in FIG. 9.

In sub-step S8044, the matched frequency f₁(h) is taken as an initial frequency for the high radio frequency power phase of a third pulse period.

In sub-step S8045, based on the initial frequency f₁(h), a matched frequency is searched for in the high radio frequency power phase of the third pulse period.

In sub-step S8046, a matched frequency f₂(h) acquired in the high radio frequency power phase of the third pulse period is read and stored.

In sub-step S8047, it is determined whether any of values of the reflection power corresponding to multiple modulation frequencies in the process of searching for the matched frequency reach the minimum value. If it is determined that one of the values of the reflection power corresponding to the multiple modulation frequencies in the process of searching for the matched frequency reaches the minimum value, sub-step S804E is performed. If it is determined that none of the values of the reflection power corresponding to the multiple modulation frequencies in the process of searching for the matched frequency reaches the minimum value, sub-step S8048 is performed.

In sub-step S8048, the matched frequency f₂(h) is taken as an initial frequency for a high radio frequency power phase of a fifth pulse period.

Similarly, if the reflection power corresponding to a matched frequency read in the high radio frequency power phase of a previous pulse period does not reach the minimum value, the step of taking the matched frequency read in the high radio frequency power phase of the previous pulse period as an initial frequency for the high radio frequency power phase of a subsequent pulse period at an interval of one pulse period from the previous pulse period and searching for a matched frequency in the high radio frequency power phase of the subsequent pulse period at an interval of one pulse period from the previous pulse period is repeated, until reflection power corresponding to a found matched frequency reaches the minimum value. Then sub-step S804E is performed.

In sub-step S804E, a modulation frequency corresponding to a value of the reflection power reaching the minimum value is determined as the first matched frequency matching the impedance of the plasma in the high radio frequency power phase of the pulse radio frequency power.

The detailed implementation of step S804 is described above. In step S804, the first matched frequency matching the impedance of the plasma in the high radio frequency power phase of the pulse radio frequency power may be acquired by using multiple consecutive odd-numbered pulse periods.

The detailed implementation of step S805 is described as follows.

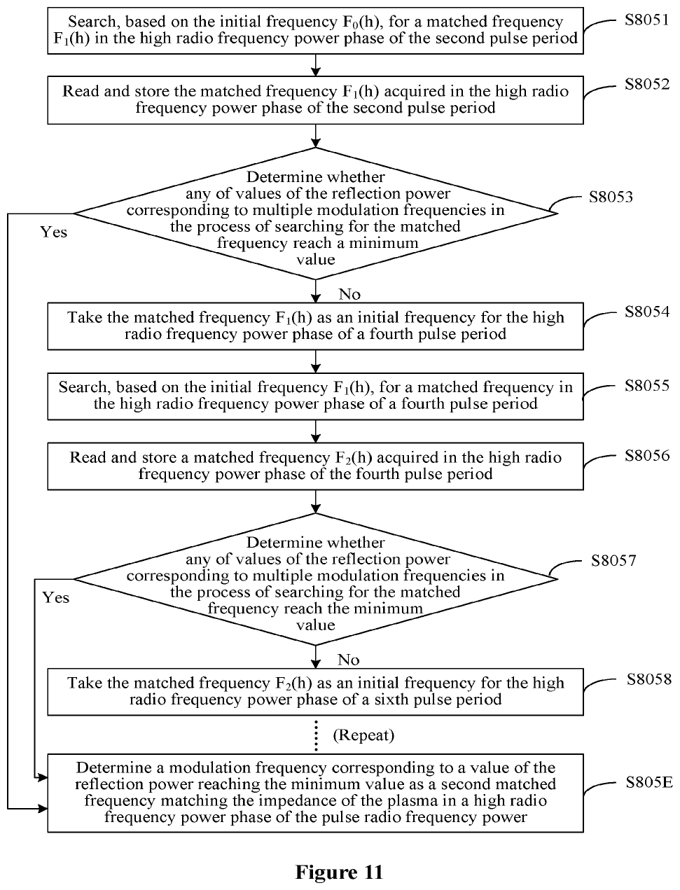

Reference is made to FIG. 11, which is a flowchart of a method for acquiring a second matched frequency according to the embodiment of the present disclosure.

In an example, step S805 may include the following sub-steps S8051 to S805E.

In sub-step S8051, based on the initial frequency F₀(h), a matched frequency F₁(h) is searched for in the high radio frequency power phase of a second pulse period.

In sub-step S8052, the matched frequency F₁(h) acquired in the high radio frequency power phase of the second pulse period is read and stored.

In sub-step S8053, it is determined whether any of values of the reflection power corresponding to multiple modulation frequencies in the process of searching for the matched frequency reach the minimum value. If it is determined that one of the values of the reflection power corresponding to the multiple modulation frequencies in the process of searching for the matched frequency reaches the minimum value, sub-step S805E is performed. If it is determined that none of the values of the reflection power corresponding to the multiple modulation frequencies in the process of searching for the matched frequency reaches the minimum value, sub-step S8054 is performed.

In sub-step S8054, the matched frequency F₁(h) is taken as an initial frequency for the high radio frequency power phase of a fourth pulse period.

In sub-step S8055, based on the initial frequency F₁(h), a matched frequency is searched for in the high radio frequency power phase of the fourth pulse period.

In sub-step S8056, a matched frequency F₂(h) acquired in the high radio frequency power phase of the fourth pulse period is read and stored.

In sub-step S8057, it is determined whether any of values of the reflection power corresponding to multiple modulation frequencies in the process of searching for the matched frequency reach the minimum value. If it is determined that one of the values of the reflection power corresponding to the multiple modulation frequencies in the process of searching for the matched frequency reaches the minimum value, sub-step S805E is performed. If it is determined that none of the values of the reflection power corresponding to the multiple modulation frequencies in the process of searching for the matched frequency reaches the minimum value, sub-step S8058 is performed.

In sub-step S8058, the matched frequency F₂(h) is taken as an initial frequency for the high radio frequency power phase of a sixth pulse period.

Similarly, if the reflection power corresponding to a matched frequency read in the high radio frequency power phase of a previous pulse period does not reach the minimum value, a step of taking the matched frequency read in the high radio frequency power phase of the previous pulse period as an initial frequency for the high radio frequency power phase of a subsequent pulse period at an interval of one pulse period from the previous pulse period and searching for a matched frequency in the high radio frequency power phase of the subsequent pulse period at an interval of one pulse period from the previous pulse period is repeated, until reflection power corresponding to a found matched frequency reaches the minimum value. Then sub-step S805E is performed.

In sub-step S805E, a modulation frequency corresponding to a value of the reflection power reaching the minimum value is determined as the second matched frequency matching the impedance of the plasma in the high radio frequency power phase of the pulse radio frequency power.

The detailed implementation of step S805 is described above. In step S805, the first matched frequency matching the impedance of the plasma in the high radio frequency power phase of the pulse radio frequency power may be acquired by using multiple consecutive even-numbered pulse periods.

It should be noted that in this embodiment, the two radio frequency modulation paths are configured, and a final result depends on a result of frequency modulation in the two radio frequency modulation paths. In practice, in an extension of this embodiment of the present disclosure, the frequency modulation may be performed in only one radio frequency modulation path, to obtain the matched frequency matching the impedance of the plasma in the high radio frequency power phase of the pulse radio frequency power.

Furthermore, in the above embodiment, the multiple pulse periods included in each of the radio frequency modulation paths are multiple inconsecutive pulse periods, and the multiple inconsecutive pulse periods are pulse periods at an interval of one pulse period. In practice, as an extension of this embodiment of the present disclosure, three or more radio frequency modulation paths may be configured. Multiple pulse periods included in each of the frequency modulation paths may be multiple inconsecutive pulse periods, and the multiple inconsecutive pulse periods are pulse periods at an interval of two or more pulse periods. A detailed implementation for a case of three or more radio frequency modulation paths is similar to that for the case of two radio frequency modulation paths, and is not described in detail herein.

It should be noted that, in the detailed implementations of steps S804 and S805, an initial frequency assigned to the high radio frequency power phase of a subsequent pulse period is a matched frequency in the high radio frequency power phase of a previous pulse period. For example, the initial frequency assigned to the high radio frequency power phase of the subsequent pulse period may be a modulation frequency corresponding to the smallest one of the multiple impedance parameters corresponding to modulation frequencies obtained in a process of searching for the matched frequency in the first radio frequency power phase of the previous pulse period. The detailed implementation is similar to that in step S203, and is not described in detail herein for brevity.

In practice, the initial frequency assigned to the high radio frequency power phase of the subsequent pulse period may also be a modulation frequency randomly read in the process of searching for the matched frequency in the first radio frequency power phase of the previous pulse period. The detail implementation is similar to that shown in FIG. 6, and is not described in detail herein for brevity.

In the method for matching an impedance of pulse radio frequency plasma according to the embodiment of the present disclosure, a matched frequency is searched for sequentially in first radio frequency power phases of the i-th pulse period and multiple consecutive pulse periods following the i-th pulse period at an interval of at least one pulse period, and a specific modulation frequency determined in a process of searching for the matched frequency in a previous pulse is assigned as an initial frequency for the subsequent pulse. In this way, it is equivalent to increasing a width of a high radio frequency power phase of a pulse period. Therefore, by performing frequency modulation sequentially in the first radio frequency power phases of the multiple pulses, a matched frequency of pulse radio frequency plasma of a high pulse frequency can be found, thereby achieving impedance matching for plasma of a high pulse frequency.

In the above three embodiments, a specific modulation frequency determined in a pulse period is taken as an initial frequency for another pulse period, so that the frequency modulation can be performed in another pulse period based on the initial frequency. Furthermore, in order to further improve accuracy of the matched frequency, a specific modulation frequency determined in a radio frequency modulation section including at least one pulse period may be taken as an initial frequency for another radio frequency modulation section, so that the frequency modulation can be performed in another radio frequency modulation section based on the initial frequency.

The radio frequency modulation sections are obtained by dividing the n pulse periods, and each radio frequency modulation section includes at least one pulse period.

For ease of illustration and description, the radio frequency modulation section is illustrated and described below with reference to drawings.

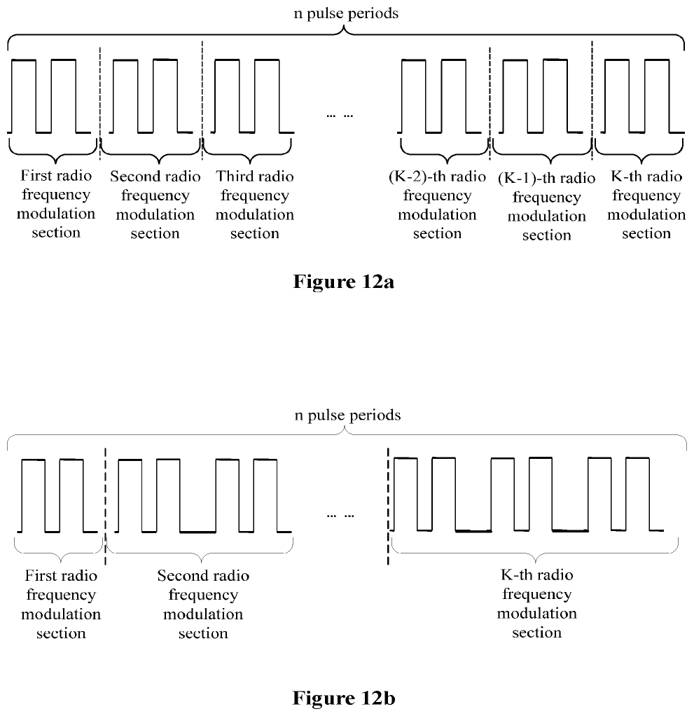

Reference is made to FIG. 12a, which is a schematic diagram of dividing pulse radio frequency power into multiple radio frequency modulation sections according to an embodiment of the present disclosure.

In this embodiment, as shown in FIG. 12a, in a case that the pulse radio frequency power includes n pulse periods, the n pulse periods may be equally divided to obtain K consecutive radio frequency modulation sections. In this case, each radio frequency modulation section includes two pulse periods.

Reference is made to FIG. 12b, which is a schematic diagram of dividing pulse radio frequency power into multiple radio frequency modulation sections according to another embodiment of the present disclosure.

In this embodiment, as shown in FIG. 12a, in a case that the pulse radio frequency power includes n pulse periods, the n pulse periods are randomly divided to obtain K consecutive radio frequency modulation sections. In this case, different radio frequency modulation sections include different numbers of pulse periods. For example, a first radio frequency modulation section includes two pulse periods, a second radio frequency modulation section includes four pulse periods, and a K-th radio frequency modulation section includes six pulse periods.

Based on the above radio frequency modulation sections, a method for frequency modulation based on radio frequency modulation sections is provided according to an embodiment of the present disclosure.

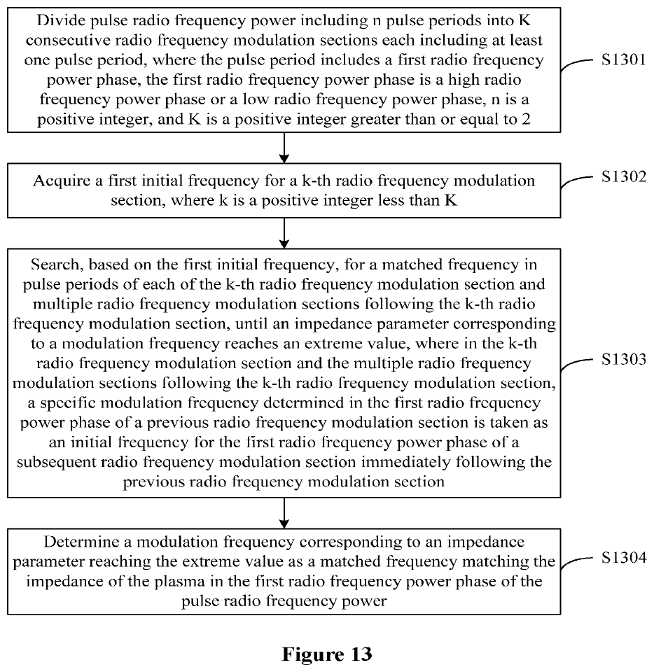

Reference is made to FIG. 13, which is a flowchart of a method for matching an impedance of pulse radio frequency plasma according to another embodiment of the present disclosure.

The method for matching an impedance of pulse radio frequency plasma according to the embodiment of the present disclosure may include the following steps S1301 to S1304.

In step S1301, pulse radio frequency power including n pulse periods is divided into K consecutive radio frequency modulation sections. Each of the radio frequency modulation sections includes at least one pulse period. The pulse period includes a first radio frequency power phase. The first radio frequency power phase is a high radio frequency power phase or a low radio frequency power phase. n is a positive integer. K is a positive integer greater than or equal to 2.

In step S1302, a first initial frequency for a k-th radio frequency modulation section is acquired, where k is a positive integer less than K.

The k-th radio frequency modulation section may be any one radio frequency modulation section from the first radio frequency modulation section to the (K−1)-th radio frequency modulation section.

As an example, this embodiment is described by taking the first radio frequency modulation section as the k-th radio frequency modulation section.

The first initial frequency may be acquired in various manners. In an example, the first initial frequency is a manually assigned frequency. In another example, the first initial frequency is a frequency obtained from previous automatic frequency modulation.

In step S1303, based on the first initial frequency, a matched frequency is searched for in pulse periods of each of the k-th radio frequency modulation section and multiple radio frequency modulation sections following the k-th radio frequency modulation section, until an impedance parameter corresponding to a modulation frequency reaches an extreme value. In the k-th radio frequency modulation section and the multiple radio frequency modulation sections following the k-th radio frequency modulation section, a specific modulation frequency determined in the first radio frequency power phases of a previous radio frequency modulation section is taken as an initial frequency for the first radio frequency power phases of a subsequent radio frequency modulation section immediately following the previous radio frequency modulation interval.

In an example, step S1303 may include the following sub-steps S13031 to S13036.

In sub-step S13031, based on the first initial frequency, a matched frequency is searched for in first radio frequency power phases of pulse periods of the k-th radio frequency modulation section. A specific modulation frequency is read and stored as a first section modulation frequency.

It should be noted that, the matched frequency may be found by performing steps of: acquiring a matched frequency matching the impedance of the plasma in the first radio frequency power phase of the pulse radio frequency power in the k-th radio frequency modulation section by using the method for matching an impedance of pulse radio frequency plasma according to the above embodiment, and taking the matched frequency as the specific modulation frequency. As described in the above embodiments, the specific modulation frequency may be a modulation frequency corresponding to the smallest one of the multiple impedance parameters corresponding to modulation frequencies obtained in a process of searching for the matched frequency in a first radio frequency power phase of a pulse period. Alternatively, the specific modulation frequency may be a modulation frequency randomly read from modulation frequencies used in a process of searching for the matched frequency in the first radio frequency power phase of a pulse period.

In sub-step S13032, it is determined whether impedance parameters corresponding to the radio frequency modulation sections in the process of searching for the matched frequency reach an extreme value. If it is determined that an impedance parameter corresponding to one of the radio frequency modulation sections in the process of searching for the matched frequency reaches the extreme value, step S1304 is performed. If it is determined that none of impedance parameters corresponding to the radio frequency modulation sections in the process of searching for the matched frequency reaches the extreme value, sub-step S13033 is performed.

In sub-step S13033, the first section modulation frequency is assigned as a second initial frequency for the first radio frequency power phase of the (k+m)-th radio frequency modulation section, where m is a positive integer and k+m≤K.

In sub-step S13034, based on the second initial frequency, a matched frequency is searched for in first radio frequency power phases of pulse periods of the (k+m)-th radio frequency modulation section. A specific modulation frequency is read and stored as a second section modulation frequency.

It should be noted that, a process of searching for the matched frequency is the same as that in sub-step S13031, and is not described in detail herein for brevity.

In sub-step S13035, it is determined whether impedance parameters corresponding to the radio frequency modulation sections in the process of searching for the matched frequency reach an extreme value. If it is determined that an impedance parameter corresponding to one of the radio frequency modulation sections in the process of searching for the matched frequency reaches the extreme value, step S1304 is performed. If it is determined that none of impedance parameters corresponding to the radio frequency modulation sections in the process of searching for the matched frequency reaches the extreme value, sub-step S13036 is performed.

It should be noted that a process of searching for the matched frequency described in this step refers to all processes of searching for the matched frequency from initial searching performed in the k-th radio frequency modulation section to the searching performed in the current radio frequency modulation section.

In sub-step S13036, a value of k is updated by k=k+m, the second section modulation frequency is taken as a second initial frequency for the first radio frequency power phase of a (k+m)-th radio frequency modulation section, and the method returns to sub-step S13034.

In an example, the multiple radio frequency modulation sections following the k-th radio frequency modulation section may be multiple consecutive radio frequency modulation sections immediately following the k-th radio frequency modulation section. In another example, the multiple radio frequency modulation sections following the k-th radio frequency modulation section may be multiple radio frequency modulation sections at an interval of at least one radio frequency modulation section from the k-th radio frequency modulation section, and at an interval of at least one radio frequency modulation section from each other.

In a case that the multiple radio frequency modulation sections following the k-th radio frequency modulation section are multiple consecutive radio frequency modulation sections immediately following the k-th radio frequency modulation section, the multiple radio frequency modulation sections may be a (k+1)-th radio frequency modulation section, a (k+2)-th radio frequency modulation section, . . . , and a (k+s)-th radio frequency modulation section, where s is a positive integer and k+s≤K.

For ease of illustration and description, the k-th radio frequency modulation section is taken as the first radio frequency modulation section in the following description. The multiple radio frequency modulation sections following the first radio frequency modulation section may be a second radio frequency modulation section, a third radio frequency modulation section, . . . , and a z-th radio frequency modulation section, where z is a positive integer less than or equal to K.

In a case that the multiple radio frequency modulation sections following the k-th radio frequency modulation section are multiple radio frequency modulation sections at an interval of at least one radio frequency modulation section from the k-th radio frequency modulation section and at an interval of at least one radio frequency modulation section from each other, the multiple radio frequency modulation sections may be a (k+m)-th radio frequency modulation section, a (k+2m)-th radio frequency modulation section, . . . , and a (k+Nm)-th radio frequency modulation section, where m is a positive integer and k+Nm≤K.

For ease of illustration and description, in the following description, the k-th first radio frequency modulation section is taken as the first radio frequency modulation section and the multiple radio frequency modulation sections are at an interval of one radio frequency modulation section. The multiple radio frequency modulation sections following the first radio frequency modulation section may be a third radio frequency modulation section, a fifth radio frequency modulation section, . . . , and a (2M−1)-th radio frequency modulation section, where M is a positive integer and 2M−1≤K.

In step S1304, a modulation frequency corresponding to an impedance parameter reaching the extreme value is determined as a matched frequency matching the impedance of the plasma in the first radio frequency power phase of the pulse radio frequency power.

The embodiment of the method for matching an impedance of pulse radio frequency plasma is described above. In this embodiment, first, the pulse radio frequency power including n pulse periods is divided into K consecutive radio frequency modulation sections. Next, the first initial frequency for the k-th radio frequency modulation section is acquired. Then, based on the first initial frequency, a matched frequency is searched for in the pulse periods of each of the k-th radio frequency modulation section and the multiple radio frequency modulation sections following the k-th radio frequency modulation section, until an impedance parameter corresponding to a modulation frequency reaches an extreme value. Finally, the modulation frequency corresponding to the impedance parameter reaching the extreme value is determined as a matched frequency matching the impedance of the plasma in the first radio frequency power phase of the pulse radio frequency power.

In addition, in the process of searching for the matched frequency in the first radio frequency power phases of the pulse periods of each of the radio frequency modulation sections, a specific modulation frequency read in a process of searching for the matched frequency in first radio frequency power phases of a previous radio frequency modulation section is assigned as an initial frequency for the subsequent radio frequency modulation section. In this way, the problem that a rate at which a power generator generates a frequency cannot match with a rate at which the modulation frequency is modulated can be solved. This assignment is equivalent to increasing a width of the first radio frequency power phases of a radio frequency modulation section. Therefore, by performing frequency modulation in the first radio frequency power phases of the multiple radio frequency modulation sections, a matched frequency of pulse radio frequency plasma of a high pulse frequency can be found, so that the impedance matching of the plasma is not limited in a single pulse, thereby achieving impedance matching of plasma of a high pulse frequency.

In order to more clearly understand the specific embodiments of the present disclosure, a process of searching for the matched frequency matching the impedance of the plasma in a high radio frequency power phase is described as an example below. The following embodiment is described with an example of taking the reflection power as the impedance parameter.

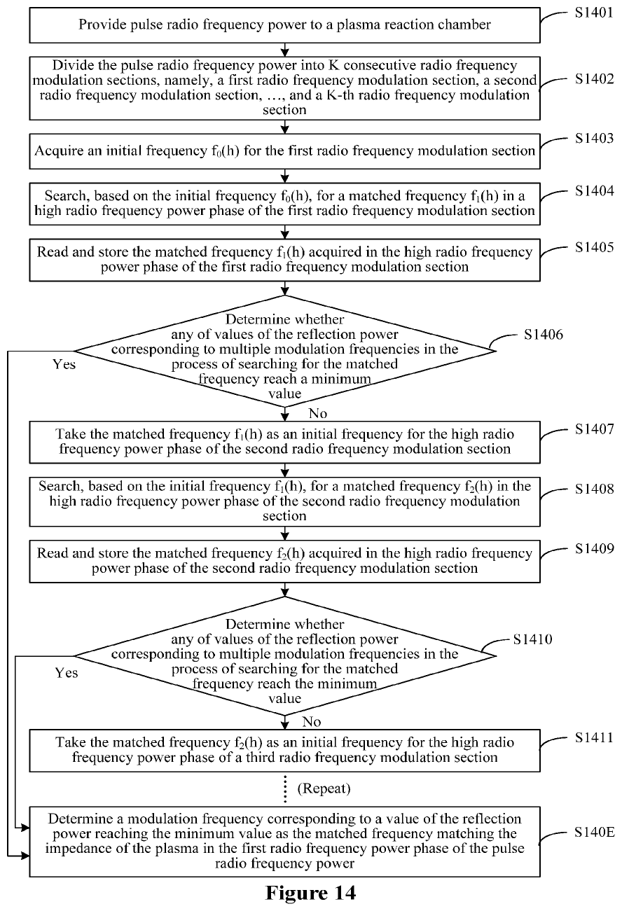

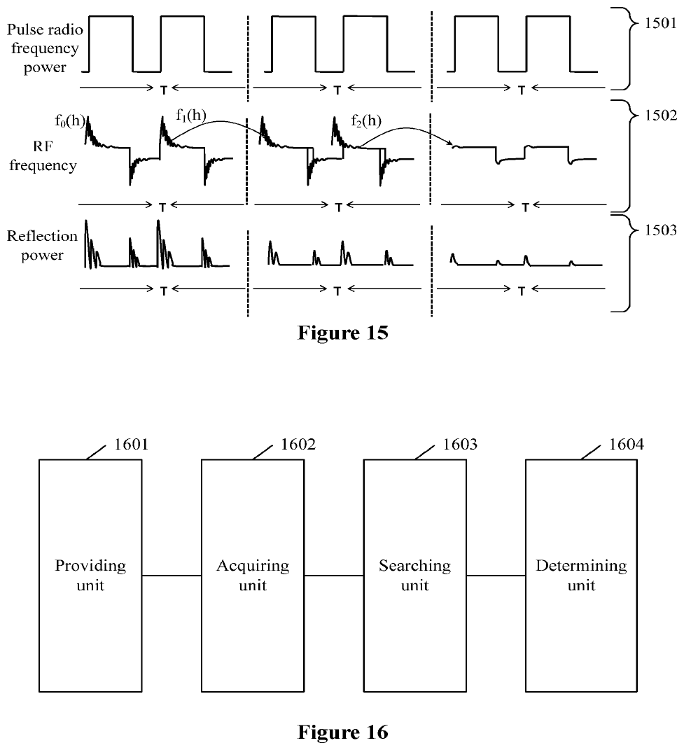

The following embodiment is illustrated and described with reference to FIGS. 14 and 15. FIG. 14 is a flowchart of a method for matching an impedance of pulse radio frequency plasma according to an embodiment of the present disclosure. FIG. 15 is a schematic diagram showing principles of the method for matching an impedance of pulse radio frequency plasma according to the embodiment of the present disclosure.

The method for matching an impedance of pulse radio frequency plasma according to the embodiment of the present disclosure may include the following steps S1401 to S140E.

In step S1401, pulse radio frequency power is provided to a plasma reaction chamber.

For example, the pulse radio frequency power may be pulse radio frequency power 1501 shown in FIG. 15.

In step S1402, the pulse radio frequency power is divided into K consecutive radio frequency modulation sections, namely, a first radio frequency modulation section, a second radio frequency modulation section, . . . , and a K-th radio frequency modulation section.

In step S1403, an initial frequency f₀(h) for the first radio frequency modulation section is acquired.

For example, the initial frequency f₀(h) may be a frequency f₀(h) of an RF frequency 1502 shown in FIG. 15.

In step S1404, based on the initial frequency f₀(h), a matched frequency f₁(h) is searched for in high radio frequency power phases of the first radio frequency modulation section.

In step S1404 of this embodiment, the matched frequency f₁(h) in the high radio frequency power phase of the first radio frequency modulation section may be acquired by using the method for matching an impedance of pulse radio frequency plasma according to any one of the above embodiments.

In step S1405, the matched frequency f₁(h) acquired in the high radio frequency power phases of the first radio frequency modulation section is read and stored.

In step S1406, it is determined whether any of values of the reflection power corresponding to multiple modulation frequencies in the process of searching for the matched frequency reach a minimum value. If it is determined that one of the values of the reflection power corresponding to the multiple modulation frequencies in the process of searching for the matched frequency reaches the minimum value, step S140E is performed. If it is determined that none of the values of the reflection power corresponding to the multiple modulation frequencies in the process of searching for the matched frequency reaches the minimum value, step S1407 is performed.

In step S1407, the matched frequency f₁(h) is taken as an initial frequency for the high radio frequency power phases of the second radio frequency modulation section.

In step S1408, based on the initial frequency f₁(h), a matched frequency f₂(h) is searched for in the high radio frequency power phases of the second radio frequency modulation section.

In step S1409, the matched frequency f₂(h) acquired in the high radio frequency power phases of the second radio frequency modulation section is read and stored.

In step S1410, it is determined whether any of values of the reflection power corresponding to multiple modulation frequencies in the process of searching for the matched frequency reach a minimum value. If it is determined that one of the values of the reflection power corresponding to the multiple modulation frequencies in the process of searching for the matched frequency reaches the minimum value, step S140E is performed. If it is determined that none of the values of the reflection power corresponding to the multiple modulation frequencies in the process of searching for the matched frequency reaches the minimum value, step S1411 is performed.

It should be noted that the process of searching for the matched frequency described in this step refers to processes of searching for the matched frequency in the first radio frequency modulation section and in the second radio frequency modulation section.

In step S1411, the matched frequency f₂(h) is taken as an initial frequency for the high radio frequency power phases of a third radio frequency modulation section.

Similarly, if the reflection power corresponding to a matched frequency read in the high radio frequency power phase of a previous radio frequency modulation section does not reach the minimum value, a step of taking the matched frequency read in the high radio frequency power phase of the previous radio frequency modulation section as an initial frequency for the high radio frequency power phase of a subsequent radio frequency modulation section immediately following the previous radio frequency modulation section and looking for a matched frequency in the high radio frequency power phase of the subsequent radio frequency modulation section immediately following the previous radio frequency modulation section is repeated, until a value of the reflection power corresponding to a read matched frequency reaches the minimum value. Then step S140E is performed.

In step S140E, a modulation frequency corresponding to a value of the reflection power reaching the minimum value is determined as the matched frequency matching the impedance of the plasma in the first radio frequency power phase of the pulse radio frequency power.

In the method for matching an impedance of pulse radio frequency plasma according to the embodiment of the present disclosure, a matched frequency is searched for sequentially in high radio frequency power phases of the i-th radio frequency modulation section and the multiple consecutive radio frequency modulation sections immediately following the i-th radio frequency modulation section, and a matched frequency found in a process of searching for the matched frequency in a previous radio frequency modulation section is assigned as an initial frequency for the subsequent radio frequency modulation section. In this way, it is equivalent to increasing a width of high radio frequency power phases of a radio frequency modulation section. Therefore, by performing frequency modulation sequentially in the high radio frequency power phases of the multiple radio frequency modulation sections, a matched frequency of pulse radio frequency plasma of a high pulse frequency can be found, so that the impedance matching of the plasma is not limited in a single pulse, thereby achieving impedance matching of plasma of a high pulse frequency.

Furthermore, in this embodiment, a matched frequency found in the high radio frequency power phases of a previous radio frequency modulation section is taken as an initial frequency for a subsequent radio frequency modulation section. In this way, the number of times of frequency modulation to be performed can be reduced, and efficiency for the frequency modulation can be improved.

The above embodiment is described by the example that the multiple radio frequency modulation sections in the process of frequency modulation are multiple consecutive radio frequency modulation sections. In practice, the multiple radio frequency modulation sections in the process of frequency modulation may be multiple inconsecutive radio frequency modulation sections at an interval of at least one radio frequency modulation section from each other.

Based on the above method for matching an impedance of pulse radio frequency plasma according to the embodiments of the present disclosure, a device for matching an impedance of pulse radio frequency plasma is further provided according to an embodiment of the present disclosure. The device for matching an impedance of pulse radio frequency plasma may be implemented in various embodiments, which are illustrated and described below with reference to the drawings.

Reference is made to FIG. 16, which is a schematic structural diagram of a device for matching an impedance of pulse radio frequency plasma according to an embodiment of the present disclosure.

In this embodiment, as shown in FIG. 16, the device for matching an impedance of pulse radio frequency plasma according to the embodiment of the present disclosure includes a providing unit 1601, an acquiring unit 1602, a searching unit 1603 and a determining unit 1604.

The providing unit 1601 is configured to provide pulse radio frequency power to a plasma reaction chamber. The pulse radio frequency power includes n pulse periods. Each of the pulse periods includes a first radio frequency power phase. The first radio frequency power phase is a high radio frequency power phase or a low radio frequency power phase, and n is a positive integer.

The acquiring unit 1602 is configured to acquire a first initial frequency for the first radio frequency power phase of an i-th pulse period, where i is a positive integer less than n.

The searching unit 1603 is configured to search, based on the first initial frequency, for a matched frequency in the first radio frequency power phase of each of the i-th pulse period and multiple pulse periods following the i-th pulse period, until an impedance parameter corresponding to a modulation frequency reaches an extreme value. In the i-th pulse period and the multiple pulse periods following the i-th pulse period, a specific modulation frequency determined for the first radio frequency power phase of a previous pulse period is taken as an initial frequency for the first radio frequency power phase of a subsequent pulse period immediately following the previous pulse period.

The determining unit 1604 is configured to determine the modulation frequency corresponding to the impedance parameter reaching the extreme value as a matched frequency matching the impedance of the plasma in the first radio frequency power phase of the pulse radio frequency power.

The device for matching an impedance of pulse radio frequency plasma according to the embodiment of the present disclosure includes the providing unit 1601, the acquiring unit 1602, the searching unit 1603 and the determining unit 1604. With this device, first, a first initial frequency for the first radio frequency power phase of an i-th pulse period is acquired. Next, based on the first initial frequency, a matched frequency is searched for in first radio frequency power phases of the i-th pulse period and the multiple pulse periods following the i-th pulse period, until an impedance parameter corresponding to a modulation frequency reaches an extreme value. Finally, the modulation frequency corresponding to the impedance parameter reaching the extreme value is determined as the matched frequency in a first radio frequency power phase of the pulse radio frequency power that matches the impedance of the plasma.

In the process of sequentially searching for the matched frequency in the first radio frequency power phases of the i-th pulse period and multiple pulse periods following the i-th pulse period, a specific modulation frequency read in a process of searching for the matched frequency in a previous pulse is assigned as an initial frequency for the subsequent pulse. In this way, the problem that a rate at which a power generator generates a frequency cannot match with a rate at which the modulation frequency is modulated can be solved. This assignment is equivalent to increasing a width of a first radio frequency power phase of a pulse period. Therefore, by sequentially performing frequency modulation in the first radio frequency power phases of the multiple pulses, a matched frequency of pulse radio frequency plasma of a high pulse frequency can be found, so that the impedance matching of the plasma is not limited in a single pulse, thereby achieving impedance matching of plasma of a high pulse frequency.

In the above embodiment, the multiple pulse periods used in a process of frequency modulation are multiple consecutive pulse periods. In addition, the multiple pulse periods used in the process of frequency modulation may be multiple inconsecutive pulse periods. The multiple inconsecutive pulse periods may be at an interval of at least one pulse period from each other.

In an embodiment, in a case that the multiple pulse periods are inconsecutive, the pulse radio frequency power including n pulse periods may be divided into multiple radio frequency modulation paths in advance. Impedance matching for the pulse radio frequency plasma is performed in each of the radio frequency modulation path, to obtain a matched frequency matching the impedance of the plasma in each of the radio frequency modulation path.

Another embodiment of the device for matching an impedance of pulse radio frequency plasma is provided, which is illustrated and described below with reference to the drawings.

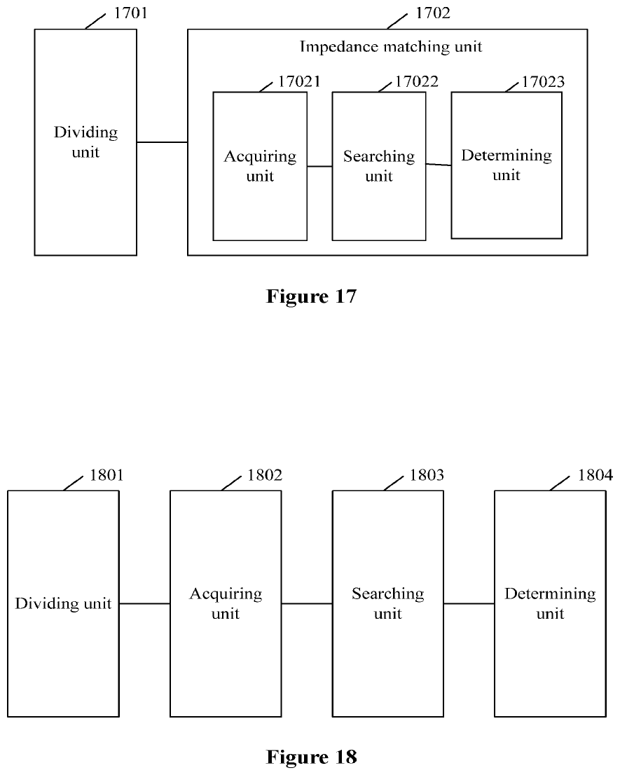

Reference is made to FIG. 17, which is a schematic structural diagram of a device for matching an impedance of pulse radio frequency plasma according to another embodiment of the present disclosure.

In this embodiment, as shown in FIG. 17, the device for matching an impedance of pulse radio frequency plasma according to the embodiment of the present disclosure includes a dividing unit 1701 and an impedance matching unit 1702.

The dividing unit 1701 is configured to divide pulse radio frequency power including n pulse periods into multiple radio frequency modulation paths in advance. Each of the multiple radio frequency modulation paths includes at least two inconsecutive pulse periods. Each of the pulse periods includes a first radio frequency power phase. The first radio frequency power phase is a high radio frequency power phase or a low radio frequency power phase, and n is a positive integer.

The impedance matching unit 1702 is configured to perform, in each of the multiple radio frequency modulation paths, impedance matching for the pulse radio frequency plasma.

The impedance matching unit 1702 includes an acquiring unit 17021, a searching unit 17022, and a determining unit 17023.

The acquiring unit 17021 is configured to acquire a first initial frequency for the first radio frequency power phase of a j-th pulse period of a radio frequency modulation path. The number of pulse periods included in the radio frequency modulation path is set as m, where m<n, and j<m, and j and m are positive integers.

The searching unit 17022 is configured to search, based on the first initial frequency, for a matched frequency in the first radio frequency power phase of each of the j-th pulse period and multiple pulse periods following the j-th pulse period in the radio frequency modulation path, until an impedance parameter corresponding to a modulation frequency reaches an extreme value. In the j-th pulse period and the multiple pulse periods following the j-th pulse period in the radio frequency modulation path, a specific modulation frequency determined in the first radio frequency power phase of a previous pulse period is taken as an initial frequency for the first radio frequency power phase of a subsequent pulse period immediately following the previous pulse period.

The determining unit 17023 is configured to determine the modulation frequency corresponding to the impedance parameter reaching the extreme value as the matched frequency matching the impedance of the plasma in the first radio frequency power phase of the pulse radio frequency power in the radio frequency modulation path.

The device for matching an impedance of pulse radio frequency plasma according to the embodiment of the present disclosure includes the dividing unit 1701 and the impedance matching unit 1702. The impedance matching unit 1702 includes the acquiring unit 17021, the searching unit 17022, and the determining unit 17023. With this device, a matched frequency is sequentially searched for in the first radio frequency power phases of an i-th pulse period and multiple pulse periods following the i-th pulse period at an interval of at least one pulse period, and a specific modulation frequency read in a process of searching for the matched frequency in a previous pulse is assigned as an initial frequency for the subsequent pulse. In this way, it is equivalent to increasing a width of a first radio frequency power phase of a pulse period. Therefore, by performing frequency modulation sequentially in the first radio frequency power phases of the multiple pulses, a matched frequency of pulse radio frequency plasma of a high pulse frequency can be found, thereby achieving impedance matching of plasma of a high pulse frequency.

In both of the above two embodiments, the matched frequency matching the impedance of the plasma is acquired via one radio frequency modulation section. Furthermore, in order to further improve accuracy of the matched frequency, the matched frequency matching the impedance of the plasma may be acquired via multiple radio frequency modulation sections.

Another embodiment of the device for matching an impedance of pulse radio frequency plasma is provided, which is illustrated and described with reference to the drawings.

Reference is made to FIG. 18, which is a schematic structural diagram of a device for matching an impedance of pulse radio frequency plasma according to another embodiment of the present disclosure.

In this embodiment, as shown in FIG. 18, the device for matching an impedance of pulse radio frequency plasma according to the embodiment of the present disclosure includes a dividing unit 1801, an acquiring unit 1802, a searching unit 1803 and a determining unit 1804.

The dividing unit 1801 is configured to divide the pulse radio frequency power including n pulse periods into K consecutive radio frequency modulation sections. Each of the radio frequency modulation sections includes at least one pulse period. The pulse period includes a first radio frequency power phase. The first radio frequency power phase is a high radio frequency power phase or a low radio frequency power phase. n is an positive integer, and K is a positive integer greater than or equal to 2.

The acquiring unit 1802 is configured to acquire a first initial frequency for a k-th radio frequency modulation section, where k is a positive integer less than K.

The searching unit 1803 is configured to search, based on the first initial frequency, for a matched frequency in pulse periods of the k-th radio frequency modulation section and multiple radio frequency modulation sections following the k-th radio frequency modulation section, until an impedance parameter corresponding to a modulation frequency reaches an extreme value. In the k-th radio frequency modulation section and the multiple radio frequency modulation sections following the k-th radio frequency modulation section, a specific modulation frequency determined in the first radio frequency power phase of a previous radio frequency modulation section is taken as an initial frequency for the first radio frequency power phase of a subsequent radio frequency modulation section immediately following the previous radio frequency modulation section.

The determining unit 1804 is configured to determine the modulation frequency corresponding to the impedance parameter reaching the extreme value as the matched frequency matching the impedance of the plasma in the first radio frequency power phase of the pulse radio frequency power.

The device for matching an impedance of pulse radio frequency plasma according to the embodiment of the present disclosure includes the dividing unit 1801, the acquiring unit 1802, the searching unit 1803 and the determining unit 1804. With this device, first the pulse radio frequency power including n pulse periods is divided into K consecutive radio frequency modulation sections. Next, a first initial frequency for a k-th radio frequency modulation section is acquired. Then, based on the first initial frequency, a matched frequency is searched for in pulse periods of each of the k-th radio frequency modulation section and multiple radio frequency modulation sections following the k-th radio frequency modulation section, until an impedance parameter corresponding to a modulation frequency reaches an extreme value. Finally, the modulation frequency corresponding to the impedance parameter reaching the extreme value is determined as a matched frequency matching the impedance of the plasma in the first radio frequency power phase of the pulse radio frequency power.

In addition, in the process of searching for the matched frequency in the first radio frequency power phases of the pulse periods of each of the radio frequency modulation sections, a specific modulation frequency read in a process of searching for the matched frequency in the first radio frequency power phases of a previous radio frequency modulation section is assigned as an initial frequency for the subsequent radio frequency modulation section. In this way, the problem that a rate at which a power generator generates a frequency cannot match with a rate at which the modulation frequency is modulated can be solved. This assignment is equivalent to increasing a width of the first radio frequency power phases of a radio frequency modulation section. Therefore, by performing frequency modulation in the first radio frequency power phases of the radio frequency modulation sections, a matched frequency of pulse radio frequency plasma of a high pulse frequency can be found, so that the impedance matching of the plasma is not limited in a single pulse, thereby achieving impedance matching of plasma of a high pulse frequency.

Based on the above method and device for matching an impedance of pulse radio frequency plasma according to the embodiments of the present disclosure, a plasma processing device is further provided according to an embodiment of the present disclosure. The plasma processing device is illustrated and described with reference to the drawings.

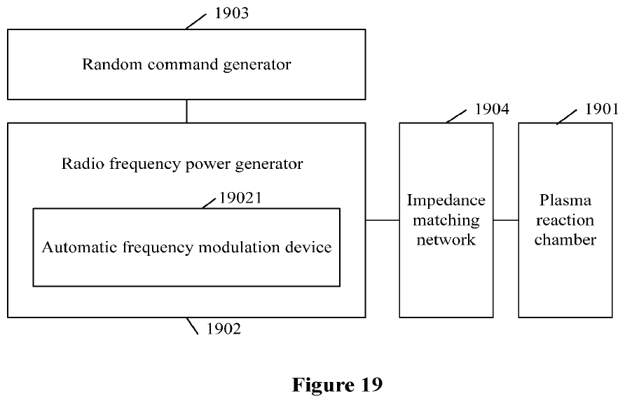

Reference is made to FIG. 19, which is a schematic structural diagram of a plasma processing device according to an embodiment of the present disclosure.

The plasma processing device according to the embodiment of the present disclosure includes a plasma reaction chamber 1901 and a radio frequency power generator 1902.

The plasma reaction chamber 1901 is configured to accommodate and process a substrate.

The radio frequency power generator 1902 is configured to output pulse radio frequency power to the plasma reaction chamber. The pulse radio frequency power includes n pulse periods each including a first radio frequency power phase. The first radio frequency power phase is a high radio frequency power phase or a low radio frequency power phase, and n is a positive integer.

The radio frequency power generator 1902 includes an automatic frequency modulation device 19021. The automatic frequency modulation device 19021 is configured to perform the above method for matching an impedance of pulse radio frequency plasma according to the embodiments of the present disclosure.

In an embodiment, the plasma processing device further includes a random command generator 1903. The random command generator 1903 is configured to set a radio frequency modulation section length, and transmit signal of the set radio frequency modulation section length to the radio frequency power generator 1902, so that the radio frequency power generator divides the n pulse periods into multiple radio frequency modulation sections based on the set radio frequency modulation section length.

In another embodiment, an impedance matching network 1904 may be arranged between the radio frequency power generator 1902 and the plasma reaction chamber 1901, to improve efficiency of feeding power to the plasma reaction chamber 1901.

The plasma processing device according to the embodiment of the present disclosure includes the plasma reaction chamber 1901 and the radio frequency power generator 1902. The radio frequency power generator 1902 includes the automatic frequency modulation device 19021. With the plasma processing device, first a first initial frequency for the first radio frequency power phase of an i-th pulse period is acquired. Next, based on the first initial frequency, a matched frequency is sequentially searched for in first radio frequency power phases of the i-th pulse period and multiple pulse periods following the i-th pulse period, until an impedance parameter corresponding to a modulation frequency reaches an extreme value. Finally, the modulation frequency corresponding to the impedance parameter reaching the extreme value is determined as a matched frequency in a first radio frequency power phase of the pulse radio frequency power that matches the impedance of the plasma.

In a process of sequentially searching for a matched frequency in the first radio frequency power phases of the i-th pulse period and the multiple pulse periods following the i-th pulse period, a specific modulation frequency read in a process of searching for the matched frequency in a previous pulse is assigned as an initial frequency for the subsequent pulse. In this way, it is equivalent to increasing a width of a first radio frequency power phase of a pulse period. Therefore, by sequentially performing frequency modulation in the first radio frequency power phases of the multiple pulses, a matched frequency of pulse radio frequency plasma of a high pulse frequency can be found, thereby achieving impedance matching of plasma of a high pulse frequency.

What is claimed is:

1. A method for matching an impedance of pulse radio frequency plasma, the method comprising:
receiving pulse radio frequency power to a plasma reaction chamber, wherein the pulse radio frequency power comprises n pulse periods each comprising a first radio frequency power phase, the first radio frequency power phase is a high radio frequency power phase or a low radio frequency power phase, and n is a positive integer;
selecting an i-th pulse period and a plurality of candidate pulse periods following the i-th pulse period, wherein i is a positive integer less than n;
acquiring a first initial frequency for the first radio frequency power phase of the i-th pulse period;
searching for a matched frequency sequentially in the first radio frequency power phase of each of the i-th pulse period and the plurality of candidate pulse periods following the i-th pulse period based on the first initial frequency, until an impedance parameter corresponding to a modulation frequency reaches an extreme value, wherein in the i-th pulse period and the plurality of candidate pulse periods following the i-th pulse period, a specific modulation frequency is randomly selected from modulation frequencies used in searching for the matched frequency in the first radio frequency power phase of the previous pulse period.

2. The method according to claim 1, wherein the selecting an i-th pulse period and a plurality of candidate pulse periods following the i-th pulse period comprises:
selecting one of the n pulse periods as the i-th pulse period; and
selecting a plurality of consecutive pulse periods immediately following the i-th pulse period as the plurality of candidate pulse periods.

3. The method according to claim 1, wherein the selecting an i-th pulse period and a plurality of candidate pulse periods following the i-th pulse period comprises:
selecting one of the n pulse periods as the i-th pulse period; and
selecting a plurality of inconsecutive pulse periods at an interval of at least one pulse period from the i-th pulse period as the plurality of candidate pulse periods.

4. The method according to claim 1, wherein the selecting an i-th pulse period and a plurality of candidate pulse periods following the i-th pulse period comprises:
dividing the n pulse periods into a plurality of radio frequency modulation paths each comprising at least two inconsecutive pulse periods; and
selecting, for each of the radio frequency modulation paths, an initial pulse period in the radio frequency modulation path as the i-th pulse period, and other pulse periods than the initial pulse period in the radio frequency modulation path as the plurality of candidate pulse periods.

5. The method according to claim 1, wherein the selecting an i-th pulse period and a plurality of candidate pulse periods following the i-th pulse period comprises:
dividing the n pulse periods into K consecutive radio frequency modulation sections each comprising at least one pulse period, wherein K is a positive integer greater than or equal to 2;
selecting each pulse period in a k-th radio frequency modulation section as the i-th pulse period, wherein k is a positive integer less than K; and
selecting pulse periods in a plurality of radio frequency modulation sections following the k-th radio frequency modulation section as the plurality of candidate pulse periods, and wherein
the specific modulation frequency determined in first radio frequency power phases of pulse periods of a previous radio frequency modulation section is taken as the initial frequency for the first radio frequency power phase of each pulse period of a subsequent radio frequency modulation section.

6. The method according to claim 4, wherein each of the radio frequency modulation paths comprises a plurality of inconsecutive pulse periods at equal intervals.

7. The method according to claim 5, wherein numbers of pulse periods in the K consecutive radio frequency modulation sections are set as any integer values.

8. The method according to claim 5, wherein the plurality of radio frequency modulation sections following the k-th radio frequency modulation section are a plurality of consecutive radio frequency modulation sections immediately following the k-th radio frequency modulation section.

9. The method according to claim 5, wherein the plurality of radio frequency modulation sections following the k-th radio frequency modulation section are a plurality of inconsecutive radio frequency modulation sections at an interval of at least one radio frequency modulation section from the k-th radio frequency modulation section.

10. The method according to claim 1, wherein the first initial frequency is a manually assigned frequency or a frequency obtained from previous automatic frequency modulation.

11. The method according to claim 1, wherein the impedance parameter is reflection power, a reflection coefficient or impedance.

12. The method according to claim 1, wherein the specific modulation frequency determined in the first radio frequency power phase of the previous pulse period is determined as:
a modulation frequency most matching the impedance of the plasma among modulation frequencies used in searching for the matched frequency in the first radio frequency power phase of the previous pulse period; or
a modulation frequency randomly determined from modulation frequencies used in searching for the matched frequency in the first radio frequency power phase of the previous pulse period.

13. A method for matching an impedance of pulse radio frequency plasma, the method comprising:
receiving pulse radio frequency power to a plasma reaction chamber, wherein the pulse radio frequency power comprises n pulse periods each comprising a first radio frequency power phase, the first radio frequency power phase is a high radio frequency power phase or a low radio frequency power phase, and n is a positive integer;
selecting a first pulse period;
acquiring an initial frequency for the first radio frequency power phase of the first pulse period;
modulating the initial frequency to find a matched frequency wherein a reflection power reaches the minimum value in the first radio frequency power phase of the first pulse period;
for each subsequent period of the n pulse periods, setting as an initial frequency of the subsequent period equal to a modulation frequency randomly determined from modulation frequencies used in searching for the matched frequency in the first radio frequency power phase of the previous pulse period.

14. A method for matching an impedance of pulse radio frequency plasma, the method comprising:
receiving pulse radio frequency power to a plasma reaction chamber, wherein the pulse radio frequency power comprises n pulse periods each comprising a first radio frequency power phase, the first radio frequency power phase is a high radio frequency power phase or a low radio frequency power phase, and n is a positive integer;
selecting an i-th pulse period and a plurality of candidate pulse periods following the i-th pulse period, wherein i is a positive integer less than n;
acquiring a first initial frequency for the first radio frequency power phase of the i-th pulse period;
modulating the first initial frequency to find a matched frequency in the first radio frequency power phase of each of the i-th pulse period and the plurality of candidate pulse periods following the i-th pulse period based on the first initial frequency, until an impedance parameter corresponding to a modulation frequency reaches an extreme value, wherein in the i-th pulse period and the plurality of candidate pulse periods following the i-th pulse period, for each subsequent pulse period setting an initial frequency for the first radio frequency power phase equal to a modulation frequency randomly determined from modulation frequencies used in searching for the matched frequency in the first radio frequency power phase of the previous pulse period.

15. The method according to claim 1, wherein the selecting an i-th pulse period and a plurality of candidate pulse periods following the i-th pulse period comprises:
selecting one of the n pulse periods as the i-th pulse period; and
selecting a plurality of consecutive pulse periods immediately following the i-th pulse period as the plurality of candidate pulse periods.

16. The method according to claim 14, wherein the selecting an i-th pulse period and a plurality of candidate pulse periods following the i-th pulse period comprises:
selecting one of the n pulse periods as the i-th pulse period; and
selecting a plurality of inconsecutive pulse periods at an interval of at least one pulse period from the i-th pulse period as the plurality of candidate pulse periods.

17. The method according to claim 14, wherein the selecting an i-th pulse period and a plurality of candidate pulse periods following the i-th pulse period comprises:
dividing the n pulse periods into a plurality of radio frequency modulation paths each comprising at least two inconsecutive pulse periods; and
selecting, for each of the radio frequency modulation paths, an initial pulse period in the radio frequency modulation path as the i-th pulse period, and other pulse periods than the initial pulse period in the radio frequency modulation path as the plurality of candidate pulse periods.

18. The method according to claim 14, wherein the selecting an i-th pulse period and a plurality of candidate pulse periods following the i-th pulse period comprises:
dividing the n pulse periods into K consecutive radio frequency modulation sections each comprising at least one pulse period, wherein K is a positive integer greater than or equal to 2;
selecting each pulse period in a k-th radio frequency modulation section as the i-th pulse period, wherein k is a positive integer less than K; and
selecting pulse periods in a plurality of radio frequency modulation sections following the k-th radio frequency modulation section as the plurality of candidate pulse periods, and wherein
the specific modulation frequency determined in first radio frequency power phases of pulse periods of a previous radio frequency modulation section is taken as the initial frequency for the first radio frequency power phase of each pulse period of a subsequent radio frequency modulation section.

19. The method according to claim 18, wherein each of the radio frequency modulation paths comprises a plurality of inconsecutive pulse periods at equal intervals.

20. The method according to claim 14, wherein the impedance parameter is reflection power, a reflection coefficient or impedance.
